(19) United States
(12) Patent Application Publication
(10) Pub. No.: US 2015/0214393 A1
(43) Pub. Date: Jul. 30, 2015

(54) SOLAR CELL AND MANUFACTURING METHOD THEREFOR

(71) Applicant: Mitsubishi Electric Corporation, Chiyoda-ku (JP)

(72) Inventors: Tetsuro HAYASHIDA, Tokyo (JP); Tatsuro WATAHIKI, Tokyo (JP); Tsutomu MATSUURA, Tokyo (JP); Takayuki MORIOKA, Tokyo (JP)

(73) Assignee: Mitsubishi Electric Corporation, Chiyoda-ku (JP)

(21) Appl. No.: 14/602,817

(22) Filed: Jan. 22, 2015

(30) Foreign Application Priority Data
Jan. 27, 2014 (JP) 2014-012748
Dec. 8, 2014 (JP) 2014-248244

(51) Int. Cl. H01L 31/0216; H01L 31/068; H01L 31/028; H01L 31/0224; H01L 31/18

(52) U.S. Cl. CPC H01L 31/02168; H01L 31/022433; H01L 31/1804; H01L 31/028; H01L 31/068

(57) ABSTRACT

A solar cell is provided that includes: a solar-battery cell that has a pn junction; a light-receiving-surface side electrode that includes a plurality of grid electrodes that are provided so as to extend in one direction at a given spacing on a light receiving surface of the solar-battery cell, and that collect a photoelectrically-converted charge; and a back-surface electrode that is provided on a back surface that opposes to the light receiving surface of the solar-battery cell. The grid electrode includes a first seed surface that comes into contact with the light receiving surface of the solar-battery cell, a second seed surface that is upright to the first seed surface, and is connected to the first seed surface, and a plated layer that comes into contact with the first seed surface and the second seed surface.

### BACKGROUND OF THE INVENTION

1. Field of the Invention

The present invention relates to a solar cell and a manufacturing method for the solar cell, and it more particularly relates to a configuration of a grid electrode and a manufacturing method for the grid electrode.

2. Description of the Related Art

The conventional crystal-system silicon solar cells that use a crystal-system silicon substrate are diffusive solar cells, heterojunction solar cells, and back-surface junction solar cells. The diffusive solar cell, which is the most common, has an impurity semiconductor layer that is formed by diffusion on the light-receiving-surface side of the substrate. In the heterojunction solar cell, an impurity semiconductor layer is formed from an amorphous-silicon semiconductor thin film or other semiconductor thin film. In the back-surface junction solar cell, an impurity semiconductor layer of the same conductivity type as the substrate and an impurity semiconductor layer of a different conductivity type from the substrate are arranged in a comb-like shape on the back-surface side of the substrate. All these types of solar cells are mass produced.

In the diffusive solar cell, a p-type crystal silicon substrate with a thickness of approximately 200 μm, for example, is used as the substrate. A surface texture that increases the light-absorption rate, an n-type diffusion layer, an anti-reflective film, and a paste surface electrode (for example, a comb-shaped silver (Ag) electrode) are formed, in the order they appear in this sentence, on the light-receiving-surface side of the substrate. A paste back-surface electrode (for example, an aluminum (Al) electrode) is formed on the non-light-receiving-surface side of the substrate by using screen printing, and thereafter firing is performed at a high temperature of approximately 800° C. In the manner as described above, the diffusive solar cell is manufactured.

In the firing described above, solvent in the paste of the surface electrode and the back-surface electrode volatilize; and on the light-receiving-surface side of the substrate, the comb-shaped Ag electrode breaks through the anti-reflective film so as to be connected to the n-type diffusion layer. Also on the non-light-receiving-surface side of the substrate, a portion of Al in the Al electrode diffuses onto the substrate so as to form a back surface field (BSC) layer.

A solar-battery cell structure that improves the photoelectric conversion efficiency is disclosed in, for example, Japanese Patent Publication No. H7-095603, Japanese Patent No. 2614561 and Japanese Patent No. 3469729, and it uses a technique related to a heterojunction solar cell, in which a junction or BSF layer, constituted by an impurity-doped silicon layer, is formed on a crystal silicon substrate via an intrinsic semiconductor thin film.

In the structure as described above, by forming an impurity-doped layer from a thin film, arbitrary concentration distribution in the impurity-doped layer can be set. Also, the impurity-doped layer is so thin that carrier recombination and light absorption within the film can be reduced. The intrinsic semiconductor layer interposed between the crystal silicon substrate and the impurity-doped silicon layer can reduce the diffusion of impurities within the junction between the crystal silicon substrate and the impurity-doped silicon layer, and it can form a junction with a steep impurity profile. Therefore, by forming an improved junction interface, a high open-circuit voltage can be obtained.

Furthermore, the intrinsic semiconductor layer and the impurity-doped layer can be formed at a relatively low temperature of approximately 200° C. Therefore, stress caused by heat on the substrate and warping of the substrate, which are problems arising when the substrate is thin, can be reduced. These layers can be expected to reduce quality degradation in a crystal silicon substrate that is prone to deteriorate due to heat. A collective electrode of this type of solar cell is generally formed by a screen printing method by means of printing silver paste patterns. The collective electrode is required to have a reduced light-shielding loss and a low wire resistance in order to improve the power generation efficiency in the solar cell.

Japanese Patent Application Laid-open No. 2013-30601 discloses a manufacturing method for a solar cell in which the width of an opening of a screen printing board is controlled such that the collective electrode has a triangular shape or a trapezoidal shape in cross section. According to this method, light that is incident to the electrode can efficiently contribute to power generation by increasing the short-circuit current of the solar cell. For example, Japanese Patent Publication No. H5-15071 and Japanese Patent Application Laid-open No. 2000-58885 disclose a manufacturing method for a solar cell that increases the conductivity of an electrode by using a photomechanical technique and a plating method. According to this manufacturing method, the fill factor of the solar cell can be increased, and thus the power-generation efficiency in the solar cell can be improved. A copper (Cu) electrode formed by plating can reduce material costs as compared to an Ag electrode. This is also effective in reducing the cost of the solar cell.

However, an electrode forming method using screen printing has a problem in that breakage of a thinned electrode is caused by poor discharge of metal paste from a printing board and thus there is a problem of low conductivity due to metal paste combined with solvent and resin. However, a high-conductivity electrode with a reduced light-shielding loss is difficult to obtain. This results in a problem that a high fill-factor solar cell is difficult to obtain.

Furthermore, in the method using the photomechanical technique and the plating method, because an electrode has a rectangular shape, light that is incident on the upper portion of the electrode cannot contribute to power generation, and therefore a high short-circuit current is difficult to obtain. In order to thin an electrode while further reducing the light-shielding loss, a high-aspect-ratio resist pattern is needed, which results in a problem of significantly increasing the difficulties in the photomechanical technique.

The present invention has been achieved to solve the above problems. There is a need to provide a solar cell that has a low-resistance electrode with a reduced light-shielding loss. There is also another need to provide a manufacturing method for a solar cell, by which a solar cell that has a low-resistance electrode with a reduced light-shielding loss can be obtained without forming a high-aspect-ratio resist pattern.

### SUMMARY OF THE INVENTION

It is an object of the present invention to at least partially solve the problems in the conventional technology.

According to an aspect of the present invention, a solar cell is provided that includes: a solar-battery cell that has a pn junction; a light-receiving-surface side electrode that includes a plurality of grid electrodes that are provided so as to extend in one direction at a given spacing on a light receiving surface of the solar-battery cell, and that collect a photoelectrically-converted charge; and a back-surface electrode that is provided on a back surface that opposes to the light receiving surface of the solar-battery cell. The grid electrode includes a first seed surface that comes into contact with the light receiving surface of the solar-battery cell, a second seed surface that is upright to the first seed surface, and is connected to the first seed surface, and a plated layer that comes into contact with the first seed surface and the second seed surface.

According to another aspect of the present invention, a manufacturing method for a solar cell is provided that includes: forming a solar-battery cell that has a pn junction; forming a light-receiving-surface side electrode that includes a plurality of grid electrodes on a light receiving surface of the solar-battery cell so as to extend in one direction at a given spacing; and forming a back-surface electrode on a back surface that opposes to the light receiving surface of the solar-battery cell. The forming a grid electrode includes forming a resist pattern that includes an opening in a region, where a grid electrode is to be formed, on a light receiving surface of the solar-battery cell, forming a seed layer in the resist pattern so as to at least include a side surface and a bottom surface facing the opening of the resist pattern, plating that includes selectively plating the seed layer to form a plated layer, and detaching the resist pattern.

According to still another aspect of the present invention, a solar cell is provided that includes: a solar-battery cell that has a pn junction; a light-receiving-surface side electrode that includes a plurality of grid electrodes that are provided so as to extend in one direction at a given spacing on a light receiving surface of the solar-battery cell, and that collect a photoelectrically-converted charge; and a back-surface electrode that is provided on a back surface that opposes to the light receiving surface of the solar-battery cell. The grid electrode is configured of a seed surface that comes into contact with the light receiving surface of the solar-battery cell, and a plated layer that comes into contact with the seed surface, and that includes a side surface that is upright from the seed surface.

The above and other objects, features, advantages and technical and industrial significance of this invention will be better understood by reading, when considered in connection with the accompanying drawings, the following detailed description of presently preferred embodiments of the invention.

### BRIEF DESCRIPTION OF THE DRAWINGS

FIG. 1 is a perspective view of a heterojunction solar-battery cell structure according to a first embodiment of the present invention;

FIGS. 2A and 2B are respectively a cross-sectional view and a top view of the heterojunction solar-battery cell structure according to the first embodiment;

FIG. 3 is a flowchart illustrating a forming process of a solar cell according to the first embodiment;

FIGS. 4A to 4E are cross-sectional views of a forming process of the solar cell according to the first embodiment;

FIGS. 5A to 5D are cross-sectional views of a forming process of the solar cell according to the first embodiment;

FIGS. 6A to 6C are cross-sectional views of a forming process of the solar cell according to the first embodiment;

FIGS. 7A and 7B are plan views and FIG. 7C is a cross-sectional view of the solar cell, all after forming a seed layer for plating in the first embodiment;

FIG. 8 is a schematic diagram illustrating relevant parts of a wafer holding jig used when forming an insulating film used in the present invention;

FIG. 9 illustrates the relation between the width of a resist opening and a substrate angle when forming an insulating film in the first embodiment;

FIG. 10 is a schematic diagram illustrating a substrate holding jig according to the first embodiment when forming an insulating film;

FIGS. 11A to 11B are plan views and FIG. 11c is a cross-sectional view, all of the solar cell after forming an insulating film according to the first embodiment;

FIG. 12 is a schematic view when performing an electrolytic plating process in the first embodiment;

FIGS. 13A and 13B are schematic explanatory diagrams illustrating an optical effect of a right-triangle electrode;

FIG. 14 is a comparative diagram illustrating an output characteristic of a photovoltaic element according to the first embodiment and that of a comparative example;

FIG. 15 illustrates a graph of the relation between an electrode width and a height of a grid electrode screen-printed in the first embodiment;

FIG. 16 is a cross-sectional view illustrating a diffusive solar-battery cell structure according to a second embodiment of the present invention;

FIG. 17 is a flowchart illustrating a forming process of a solar cell according to the second embodiment;

FIGS. 18A to 18D are cross-sectional views of a forming process of the solar cell according to the second embodiment;

FIGS. 19A to 19C are cross-sectional views of a forming process of the solar cell according to the second embodiment;

FIGS. 20A to 20C are cross-sectional views of a forming process of the solar cell according to the second embodiment;

FIGS. 21A to 21C are cross-sectional views of a forming process of the solar cell according to the second embodiment;

FIGS. 22A to 22C are cross-sectional views of a forming process of the solar cell according to the second embodiment;

FIG. 23 is a cross-sectional view illustrating a diffusive solar-battery cell structure according to a third embodiment of the present invention;

FIG. 24 is a flowchart illustrating a forming process of a solar cell according to the third embodiment;

FIGS. 25A to 25D are cross-sectional views of a forming process of the solar cell according to the third embodiment;

FIGS. 26A to 26D are cross-sectional views of a forming process of the solar cell according to the third embodiment;

FIGS. 27A to 27C are cross-sectional views of a forming process of the solar cell according to the third embodiment;

FIGS. 28A to 28C are cross-sectional views of a forming process of the solar cell according to the third embodiment;

FIGS. 29A to 29C are cross-sectional views of a forming process of the solar cell according to the third embodiment;

FIGS. 30A to 30C are cross-sectional views of a forming process of the solar cell according to the third embodiment;

FIG. 31 is a cross-sectional view of a forming process of a solar cell according to a fourth embodiment of the present invention;

FIG. 32 is a cross-sectional view of a forming process of a solar cell according to a fifth embodiment of the present invention;

FIG. 33 is a cross-sectional view of a forming process of a solar cell according to a sixth embodiment of the present invention;

FIG. 34 is a cross-sectional view of a forming process of a solar cell according to a seventh embodiment of the present invention;

FIG. 35 is a cross-sectional view of a forming process of a solar cell according to an eighth embodiment of the present invention;

FIG. 36 is a comparative diagram illustrating a relation between the height of a grid electrode and the output characteristic of the solar cell according to the eighth embodiment; and

FIG. 37 is a cross-sectional view illustrating a heterojunction solar-battery cell structure according to a ninth embodiment of the present invention.

### DETAILED DESCRIPTION OF THE PREFERRED EMBODIMENTS

Exemplary embodiments of a solar cell and a manufacturing method therefor according to the present invention will be described below in detail with reference to the accompanying drawings. The present invention is not limited to the following descriptions and can be modified as appropriate without departing from the scope of the invention. In the drawings illustrated below, the scale of each layer or each member is sometimes different from the actual scale thereof for the sake of easy understanding. The scale of the drawings is also different. Hatching is sometimes illustrated even in a plan view for ease of viewing the drawings.

### First Embodiment

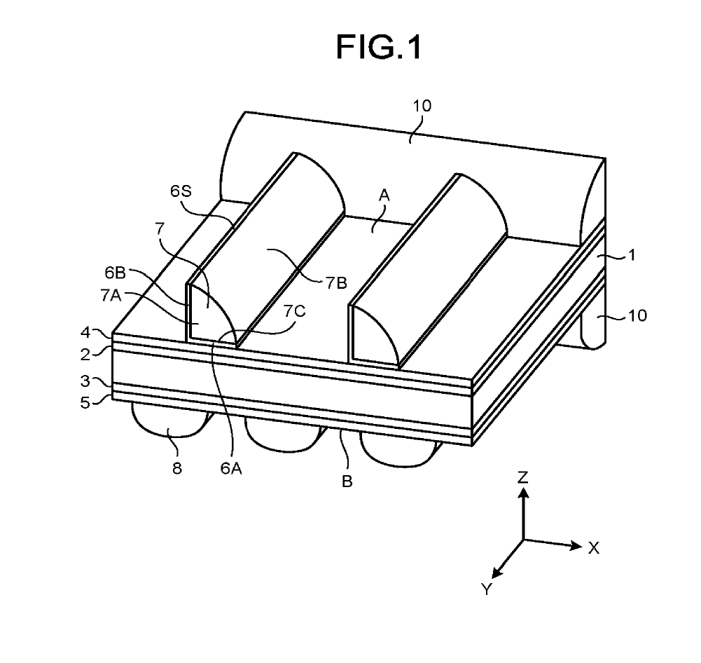

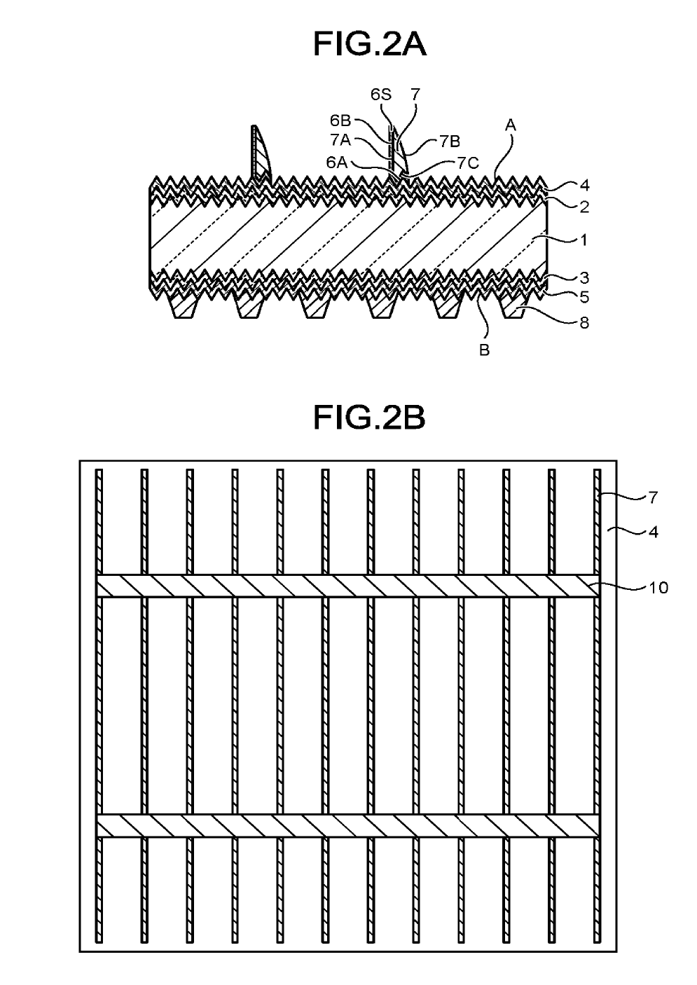

FIG. 1 is an enlarged perspective view of the relevant parts of a solar cell according to a first embodiment of the present invention. FIGS. 2A and 2D are respectively a cross-sectional view and a top view schematically illustrating the configuration of the solar cell according to the first embodiment of the present invention. FIG. 1 is a perspective view illustrating the cross-sectional structure of a region R₀ near the intersection between a bus electrode 10 and a grid electrode 7. In the present invention, the axis parallel to the direction in which the bus electrode 10 extends is defined as the “X-axis”; the axis parallel to the extending direction of the grid electrode 7 is defined as the “Y-axis”; and the axis perpendicular to both the X-axis and the Y-axis is defined as the “Z-axis”. The solar cell according to the first embodiment uses a heterojunction solar-battery cell, in which an amorphous silicon-system thin film with a bandgap different from that of a single-crystal silicon substrate is formed on the surface of the single-crystal silicon substrate so as to form a heterojunction. The solar cell according to the first embodiment is constituted by a heterojunction solar-battery cell, and it includes a collective electrode on a photoelectric conversion element thereon, wherein an insulating film is formed on a resist opening in an oblique direction such that a seed layer to be plated is exposed only on the side surface and the lower portion of the resist opening, from which a plated coating is grown in a lateral direction.

The solar cell according to the first embodiment includes a single-crystal silicon substrate 1, on a surface of which an irregular structure, referred to as “texture”, is formed. On the side of a light receiving surface A of the single-crystal silicon substrate 1, a light-receiving-surface side amorphous silicon layer 2; a light-receiving-surface side translucent electrode 4; a seed layer 6S to be plated; and the grid electrode 7 are stacked. On the side of a back surface 8, a back-surface side amorphous silicon layer 3; a back-surface side translucent electrode 5; and a back-surface electrode 8 are stacked in the order they appear in this sentence. In this solar cell, light to be photoelectrically converted is incident from a side of the single-crystal silicon substrate 1, on which the light-receiving-surface side amorphous silicon layer 2 is formed, that is, from the side of the light receiving surface A.

The grid electrode 7 is configured in a plated layer pattern with a right angled triangle shape in cross section, which includes a first surface 7A that is vertical to the light receiving surface A; a second surface 7B that is inclined with an acute angle relative to the first surface 7A; and a bottom surface 7C that comes into contact with the light receiving surface A.

The plated layer pattern that constitutes the grid electrode 7 has been grown from the seed layer 6S. The seed layer 6S has an L shape in cross section; and it includes a first seed surface 6A that comes into contact with the light receiving surface A and a second seed surface 6B that is perpendicular to the first seed surface 6A. This plated layer pattern is a right-triangle pattern in cross section constituted by a plated layer that has grown isotropically from the first and second seed surfaces 6A and 6B, and that comes into contact with the first and second seed surfaces 6A and 6B. Because the substrate 1 is formed with the texture structure, the shape of the substrate 1 is magnified in FIG. 2A. However, the bottom surface 7C constitutes a horizontal surface in practice. A grid electrode is configured from the first seed surface 6A, the second seed surface 6B, and a plated layer that has been grown from the first seed surface 6A and the second seed surface 6B.

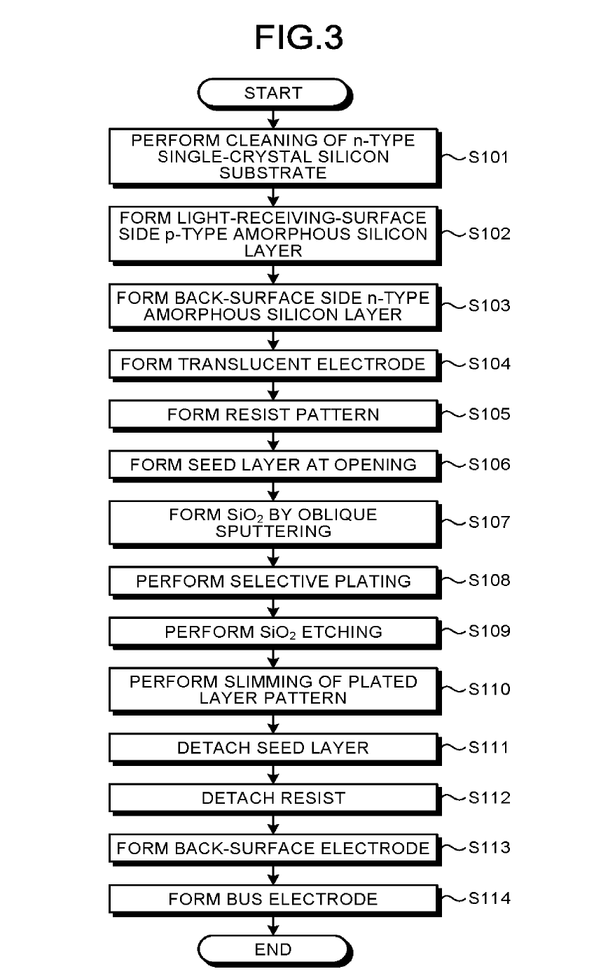

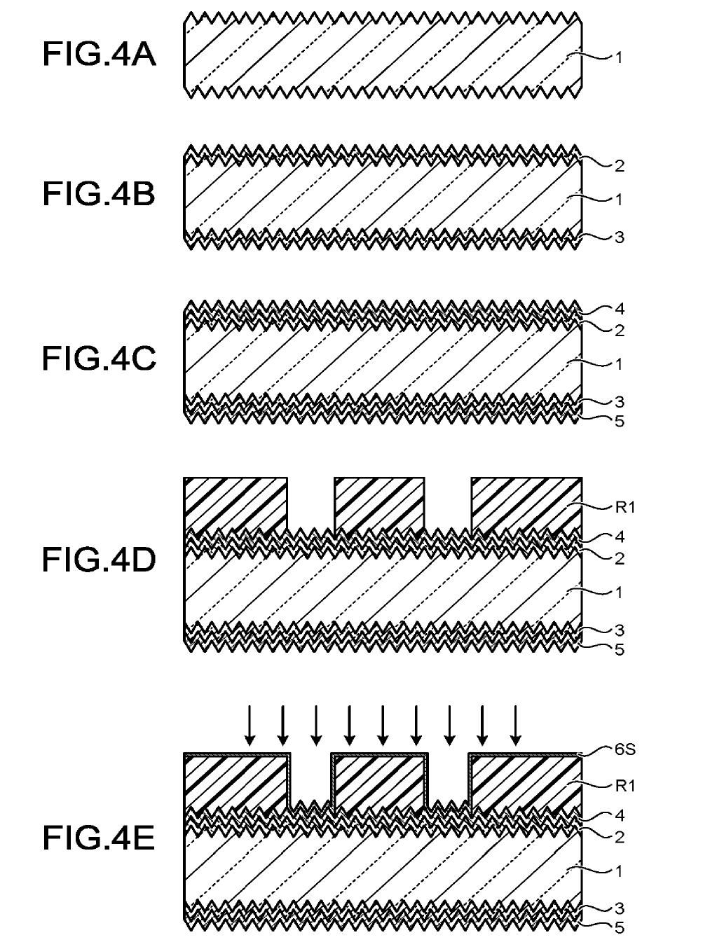

Next, a manufacturing method for the solar cell according to the first embodiment configured as above is described with reference to the flowchart illustrated in FIG. 3 and with reference to FIGS. 4A to 4E, FIGS. 5A to 5D, and FIGS. 6A to 6C. FIGS. 4A to 4E, FIGS. 5A to 5D, and FIGS. 6A to 6C are cross-sectional views illustrating an example of a procedure of the manufacturing method for the solar cell according to the first embodiment.

First, a substrate is cleaned; and on its surface, the single-crystal silicon substrate 1 with an irregular structure referred to as “texture 1T” is formed (S101 in FIG. 4A). That is, the single-crystal silicon substrate 1 is sliced from a single-crystal silicon ingot, and thereafter the irregular structure is formed on the surface of the single-crystal silicon substrate 1 by wet etching using an alkaline water solution such as a NaOH water solution or a KOH water solution. The texture 1T reduces the reflection of light incident on a solar cell and promotes light scattering within the solar cell. In the single-crystal silicon substrate 1, the etching rate using an alkaline water solution differs depending on the plane orientation. Therefore, when a single-crystal silicon substrate is etched on a surface with a plane orientation (100) for example, a surface with a plane orientation (111) which is not easily etched, appears in an oblique direction. Eventually, a pyramid-shaped irregular structure is provided on this single-crystal silicon substrate 1.

From the viewpoint of productivity, the single-crystal silicon substrate 1 is sliced from a single-crystal silicon ingot, then an irregular structure is formed on its surface, and thereafter an amorphous silicon layer is formed. Therefore, when any damage caused by slicing, a metal smear, or the like remains on a silicon substrate, the irregular structure cannot appropriately be controlled. At the interface between single-crystal silicon and amorphous silicon, recombination of electron carriers, generated by photoelectrical conversion within the single-crystal silicon substrate 1, occurs. This deteriorates the characteristics of the solar cell. Accordingly, it is preferable to provide treatment to the single-crystal silicon substrate 1 after slicing, such as gettering or cleaning by using hydrogen peroxide or other chemicals.

The single-crystal silicon substrate 1 can be either a p-type silicon substrate or an n-type silicon substrate. However, in the case of forming a p-type light-receiving-surface side amorphous silicon layer on the light-receiving-surface side of the single-crystal silicon substrate 1, it is preferable to provide an n-type silicon substrate as the single-crystal silicon substrate 1 such that incident light can immediately reach a pn junction. In contrast, in the case of forming an n-type amorphous silicon layer on the light-receiving-surface side of the single-crystal silicon substrate 1, it is preferable to provide a p-type silicon substrate as the single-crystal silicon substrate 1. In this example, the single-crystal silicon substrate 1 is described as an n-type silicon substrate. Note that the single-crystal silicon substrate 1 is provided in this example; however, a polycrystalline silicon substrate or other crystal-system semiconductor substrates usable for a solar cell, such as a SiGe semiconductor substrate, can also be used instead of a crystal silicon substrate.

After the irregular structure is formed on the single-crystal silicon substrate 1, the light-receiving-surface side amorphous silicon layer 2 is formed as a semiconductor layer with a bandgap different from that of the crystal silicon on the light-receiving-surface side of the single-crystal silicon substrate 1 as illustrated in FIG. 4B by using a chemical-vapor deposition (CVD) method, for example (S102). In this example, because the single-crystal silicon substrate 1 is supposed to be of an n-type, the light-receiving-surface side amorphous silicon layer 2 is set to be of a p-type. The light-receiving-surface side amorphous silicon layer 2 preferably has a high carrier concentration in order to improve the conductivity, and it further preferably has a high light transmission rate because the light-receiving-surface side amorphous silicon layer 2 is arranged on the light-receiving-surface side. In order to achieve the high carrier concentration and high light transmission rate, the light-receiving-surface side amorphous silicon layer 2 can be a thin-film p-type microcrystal silicon layer. While a heterojunction is formed on the interface between the crystal silicon and amorphous silicon, an i-type amorphous silicon layer and a p-type light-receiving-surface side amorphous silicon layer 2 can be stacked, in the order they appear in this sentence, on the light-receiving-surface side of a crystal silicon substrate as passivation in order to form a BSF structure.

On the back-surface side, an n-type back-surface side amorphous silicon layer 3 is formed (S103). A junction between the n-type back-surface side amorphous silicon layer 3 and an n-type back-surface side translucent electrode 5 is formed. Therefore, the contact between the n-type back-surface side amorphous silicon layer 3 and the n-type back-surface side translucent electrode 5 can be more easily established compared with that of the light-receiving-surface side. Also in this case, it is preferable for the back-surface side amorphous silicon layer 3 to have a high carrier concentration, a high light transmission rate, and, particularly, a high infrared-light transmission rate. In order to achieve these high carrier concentrations and high light transmission rates, the back-surface side amorphous silicon layer 3 can be a thin-film n-type microcrystal silicon layer.

Subsequently, as illustrated in FIG. 4C, the light-receiving-surface side translucent electrode 4 and the back-surface side translucent electrode 5 are formed by using, for example, a sputtering technique and an ion plating technique (S104). It is more preferable that the light-receiving-surface side translucent electrode 4 and the back-surface side translucent electrode 5 are made of a material with a high light transmission rate and high conductivity. Preferable materials to be used for the above electrodes are, for example, indium oxide, titanium oxide, zinc oxide, and tin oxide. In order to improve the conductivity, a minute amount of metal such as Al, Ga, Nb, or Sn can be doped with these materials. In order to increase the light transmission rate, after a film is formed from these materials, annealing can be performed on the film in a reducing atmosphere, for example in hydrogen, or in a vacuum.

Subsequently, a resist film R1 is spin-coated and its thickness is adjusted to approximately 40 μm, and thereafter exposure and developing treatment is performed so as to obtain a resist pattern with an opening as illustrated in FIG. 4D (S105). A resist material, to be preferably used at this process, is a high-viscosity resist capable of forming a thick film. For example, “PMER P-CR4000PM” manufactured by TOKYO OHKA KOGYO CO., LTD. is used. Next, as illustrated in FIG. 4E, the seed layer 6S is formed on the top of the resist film R1 so as to make contact with the opening (S106). The seed-layer forming technique used is, for example, DC magnetron sputtering or electron-beam vapor-deposition. It is preferable for a seed layer to be made of a material with high conductivity, for example, silver or copper. From the viewpoint of ensuring adhesion of the seed layer 6S, a stacking structure can be employed, in which Ti, Ni, Cr, or another element is interposed between the light-receiving-surface side translucent electrode 4 and the seed layer 6S. While the substrate has the seed layer 6S on its entire surface as described above, a region, where the seed layer 6S and the substrate directly make contact with each other, is limited only to a resist opening. Therefore, reduction of electric-field distribution when the plating is performed and a reduction in plasma damage when a seed layer is formed can both be achieved.

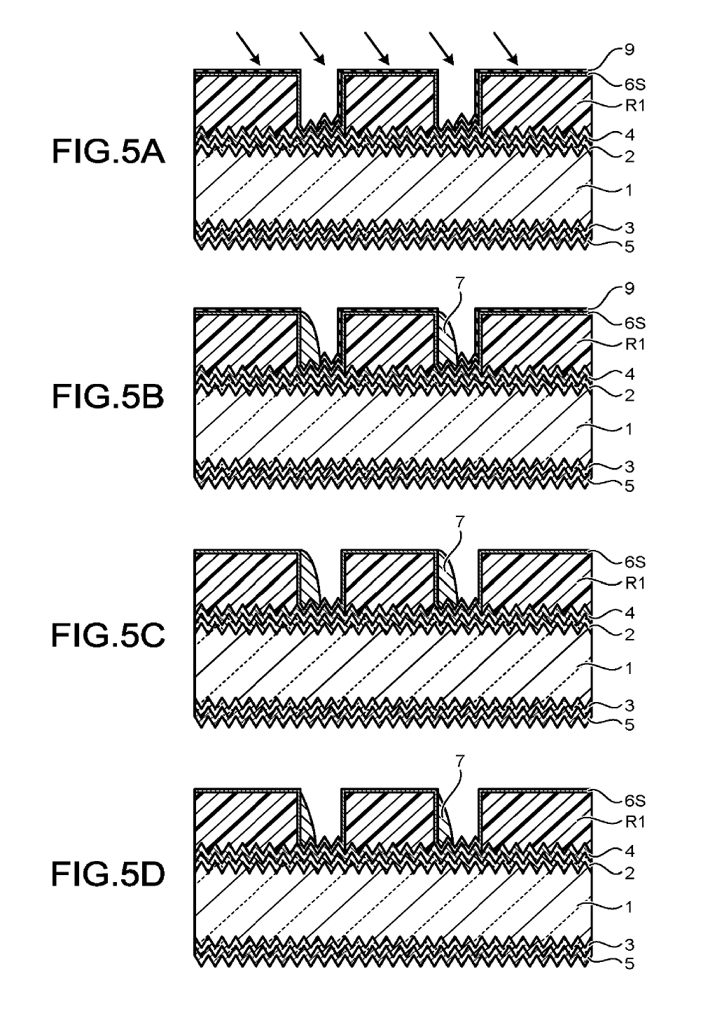

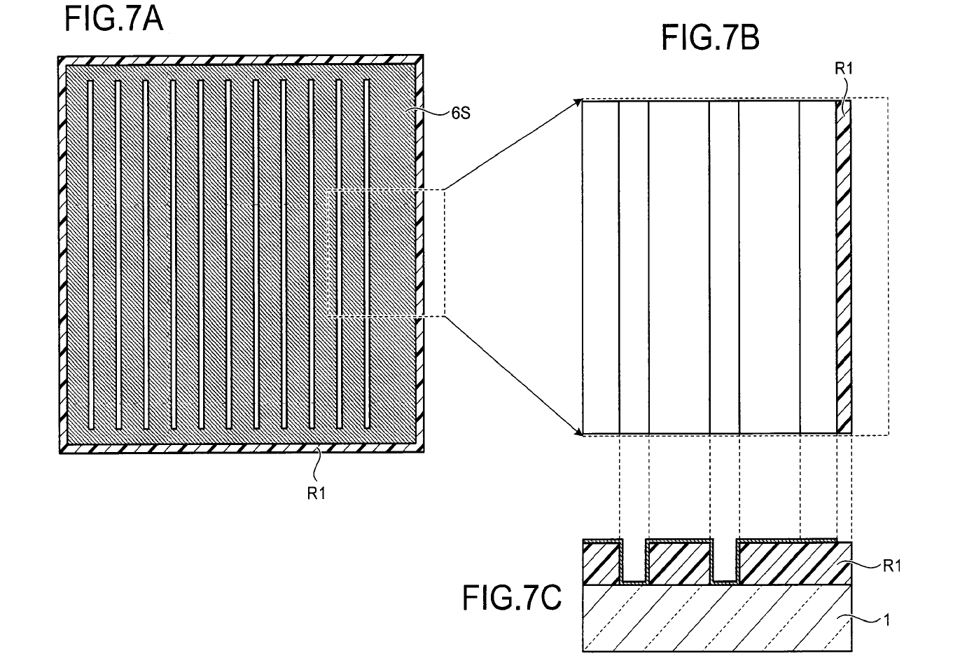

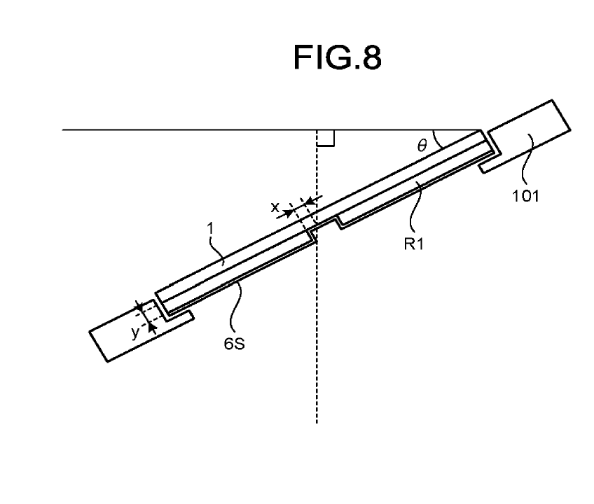

FIGS. 7A and 7B are plan views and FIG. 7C is a cross-sectional view, all of a substrate obtained when finishing the process in FIG. 4E. Because when forming a metal film, a substrate peripheral portion is blocked by a substrate holding jig, the seed layer 6S is not formed on the substrate peripheral portion, and therefore the substrate peripheral portion is in a state where the resist film R1 is exposed. Although not illustrated in FIG. 7C, the texture is formed in the same manner as illustrated in FIG. 2A. Subsequently, as illustrated in FIG. 5A, an insulating film 9 is formed with oblique incident angle to the substrate (S107). The material used for the insulating film 9 is, for example, silicon dioxide (SiO₂). The film forming technique used is, for example, RF magnetron sputtering. By decreasing the sputtering pressure during film formation, sputtering particles can be sprayed more straightly so as to reduce formation of the insulating film 9 on unnecessary portions. As a result of this, the seed layer 6S is exposed only on one side-surface of a resist opening and immediately below the one side-surface. FIG. 8 illustrates an inclination angle of a substrate when an insulating film is being formed. The single-crystal silicon substrate 1 is fitted onto a counterbore portion 103 provided in a substrate holding jig 101. The bottom line-width of a grid electrode indicates the line width of a region where the grid electrode makes contact with an underlying substrate. The upper line-width of a grid electrode indicates the line width of a portion excluding the bottom of the grid electrode. A substrate angle θ when forming the insulating film 9 is uniquely determined by a bottom line-width “x” of a grid electrode and a resist thickness “y”, and is expressed by the following expression (1).

$$θ = 90 - {sin}^{- 1} \frac{y}{\sqrt{{x}^{2} + {y}^{2}}} \qquad ( 1 )$$

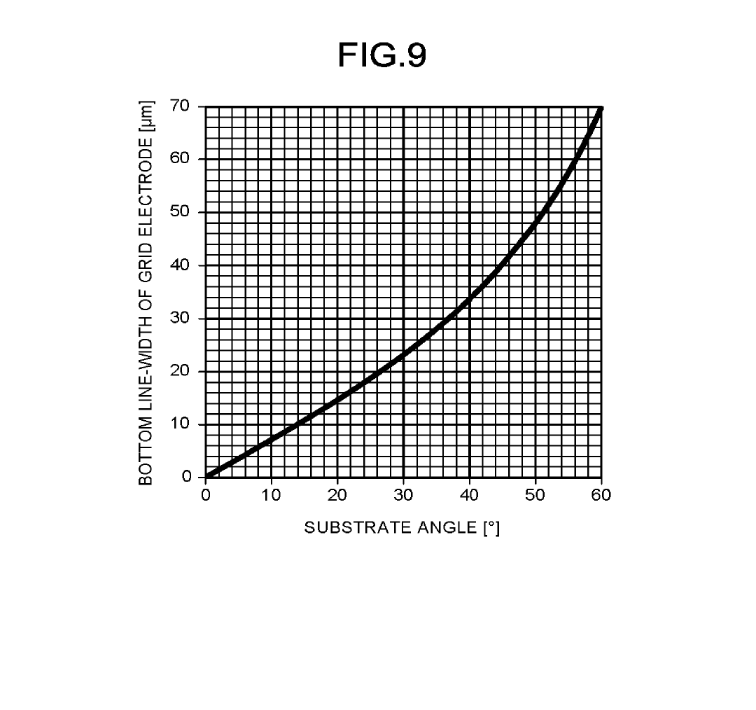

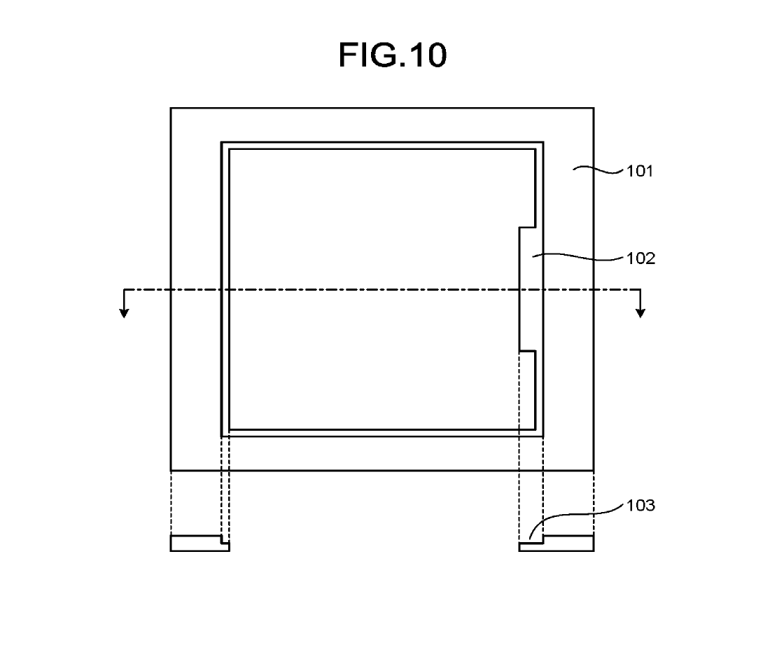

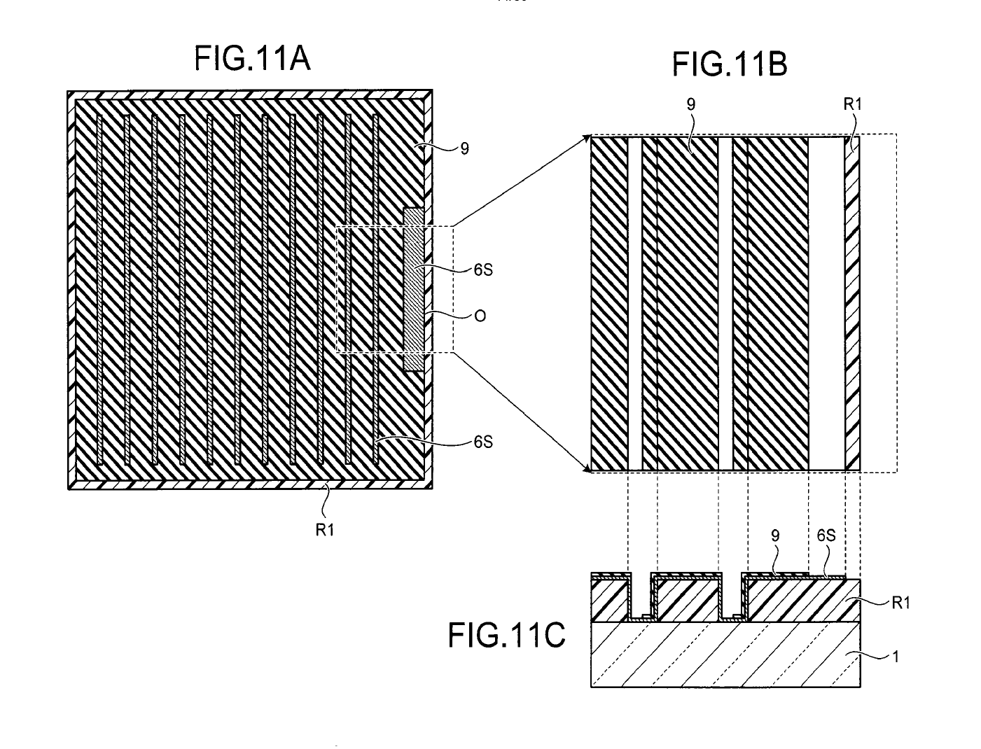

FIG. 9 illustrates the relation between a substrate angle and the bottom line-width “x” of a grid electrode when the resist thickness is, for example, 40 μm. It is understood that the bottom line-width “x” of a grid electrode can be controlled freely by adjusting the substrate angle θ. When forming the insulating film 9, the substrate holding jig 101 with a structure as illustrated in FIG. 10 is used. By providing a substrate mask portion 102, the insulating film 9 can be prevented from being formed on the corresponding location on the substrate. FIGS. 11A to 11B are plan views and FIG. C is a cross-sectional view, all of a substrate obtained after forming the insulating film 9. The insulating film 9 is formed through the substrate mask portion 102 on the substrate, such as an n-type single-crystal silicon substrate, positioned at the counterbore portion 103 of the substrate holding jig 101, and therefore a seed-layer exposed portion O is formed on one side of the substrate. The location that corresponds to this is used later as a feeding point when the plating is performed.

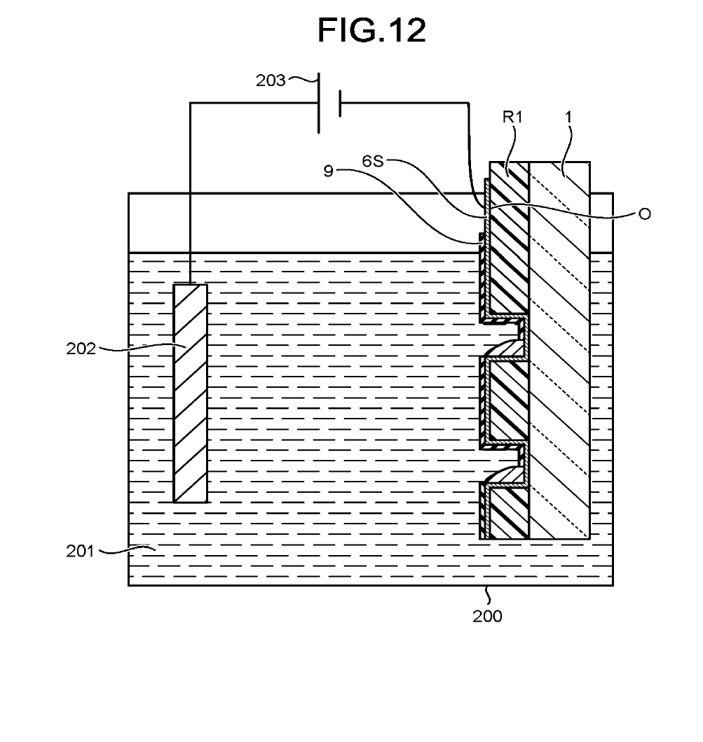

Subsequently, the seed-layer exposed portion O to be plated is cleaned with dilute sulfuric acid or another agent; and thereafter plating is performed using a plating bath 200 filled with a copper sulfate solution 201 as illustrated in FIG. 12 so as to form a plated layer selectively on the seed-layer exposed portion O (S108). The single-crystal silicon substrate 1 and a copper plate 202 are soaked in the copper sulfate solution 201 so as to apply a voltage from a power supply 203 between the copper plate as an anode and the substrate side as a cathode. It is desirable that at this time, the plating current is equal to or lower than 6 A/dm² in order to obtain a high quality coating. The plating time is determined according to a target line width of a grid electrode. The substrate feeding point is the seed-layer exposed portion O on one side of the substrate described above. It is preferable to perform plating treatment in a state where the seed-layer exposed portion O is out of the copper sulfur solution 201. This can prevent a feeding terminal and the seed-layer exposed portion O, which is the feeding point, from becoming bonded to each other with a plating coating.

A technique for growing a plated coating from one side-surface of a resist opening as described above is effective also in reducing the occurrence of breakage of a thinned electrode. This is because in the technique of the present invention, the line width of the grid electrode 7 is not related to the width of the resist opening, which is in contrast to a technique using a known photomechanical technique in which the grid line-width is affected by the width of the resist opening. That is, the bottom line-width of the grid electrode 7 is controlled by the substrate angle θ when the insulating film 9 is formed, and the upper line-width of the grid electrode 7 is controlled by the plating time. That is, as described above, by using the technique for forming a film selectively on the region that is the seed-layer exposed portion O where the insulating film 9 is not formed as a result of formation of the insulating film 9 by oblique sputtering, the bottom line-width of the grid electrode 7 is controlled by the substrate angle when the insulating film 9 is formed. The seed layer 6S is exposed on a side wall of a resist and a portion of the bottom of the resist, which are blocked portions from the formation of the insulating film 9 by oblique sputtering. Because a plated layer grows from the seed-layer exposed portion O, the upper line-width of the grid electrode 7 can be controlled by the plating time. Therefore, according to the technique in the first embodiment, the grid electrode 7 can be thinned without forming a high-aspect-ratio resist pattern. Accordingly, the occurrence of breakage of the grid electrode 7 is reduced, and the yield ratio is improved.

Further, because a plated coating is grown not only from the bottom of a resist opening but also from the side surface of the opening, the plating speed can be increased. The rate of increase in plating speed at this time is expressed as “(grid height+grid width)/grid width”. For example, in the case where an electrode with a grid width of 20 μm and a grid height of 40 μm is formed, given that the current density is constant when the plating performed, a plating speed that is three times as fast as that in a general technique can be achieved. FIG. 5B illustrates a cross-sectional view of a substrate obtained after electrolytic plating.

In a case where the grid electrode 7 is desired to be further thinned, after etching of the insulating film 9 (at S109: FIG. 5C), slimming of a plated layer pattern (at S110) can be performed. This slimming is carried out by soaking the substrate in a copper selective etching solution. In this manner, the grid electrode 7 can have a right angled triangle shape in cross section with the inclination angle exceeding 45 degrees as illustrated in FIG. 5D. While the slimming is performed by isotropic etching, the grid height is reduced along with a decrease in the grid width. Therefore, while the light-shielding loss is reduced by slimming, the inclination angle remains unchanged. Note that the slimming can be performed by anisotropic etching.

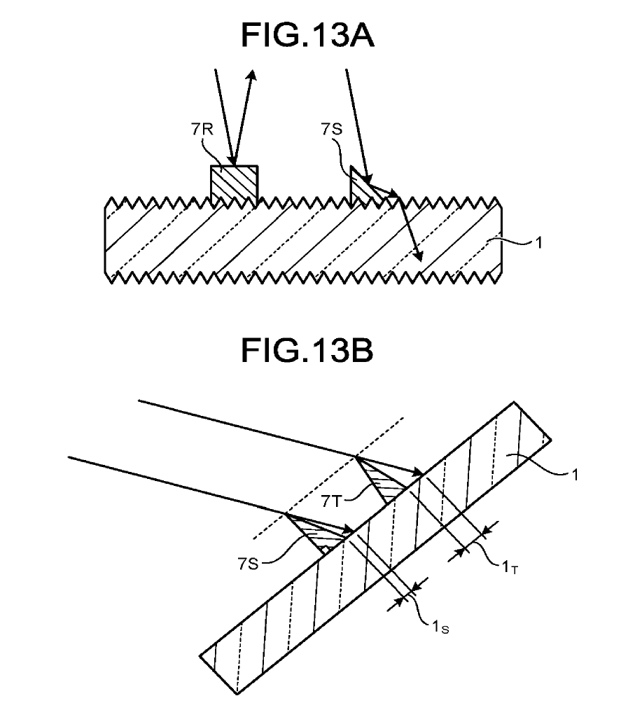

Next, the relation between the electrode cross-sectional shape and the power generation amount is described. FIG. 13A is an explanatory diagram illustrating the relation between a general rectangular-shaped electrode 7R and a right angled triangle shaped electrode 7S. As illustrated in FIG. 13A, light incident on the right angled triangle shaped electrode 7S is reflected on the side surface of the electrode 7S, and it is then incident on the single-crystal silicon substrate 1. Therefore, the power generation amount can be increased. This means that the real electrode light-shielding loss is actually decreased. The right-angled-triangular electrode 7S is apparently different from the rectangular electrode 7R in which light incident on the upper portion of the electrode is reflected upward. Further, in the first embodiment, the grid electrode 7 does not have a tapered shape on both sides, but has a shape in which the first surface 7A that is one of the elevation surfaces is vertical to the substrate surface, and the second surface 7B that is the other elevation surface forms an acute angle relative to the first surface 7A. Therefore, the grid electrode 7 can be formed so as to have a larger inclination angle with respect to the aspect ratio. Accordingly, the grid electrode 7 can be formed with a low specific resistance per unit area, while reducing an increase in the light-shielding area. A solar-cell module can be installed in such a manner that optimum lighting can be achieved for the second surface inclined relative to the light receiving surface of a solar-battery cell. FIG. 13B illustrates a comparative diagram of an electrode light-shielding loss caused by the electrode 7S that has a right-angled-triangular shape in cross section and by an electrode 7T that has a tapered shape on both sides. The light-shielding widths, represented by 1_{S} and 1_{T}, are portions other than electrode portions constituted respectively by the right angled triangle shaped electrode 7S and the electrode 7T with a tapered shape on both sides that shield the light. The light-shielding width 1_{S} of the right-angled-triangular electrode 7S is obviously smaller. As described above, it is possible for the electrode 7S with a right-angled-triangular shape in cross section to have a lower light-shielding loss in a portion other than the electrode portion, and therefore to increase the photoelectric conversion efficiency when compared with the electrode 7T with a tapered shape on both sides.

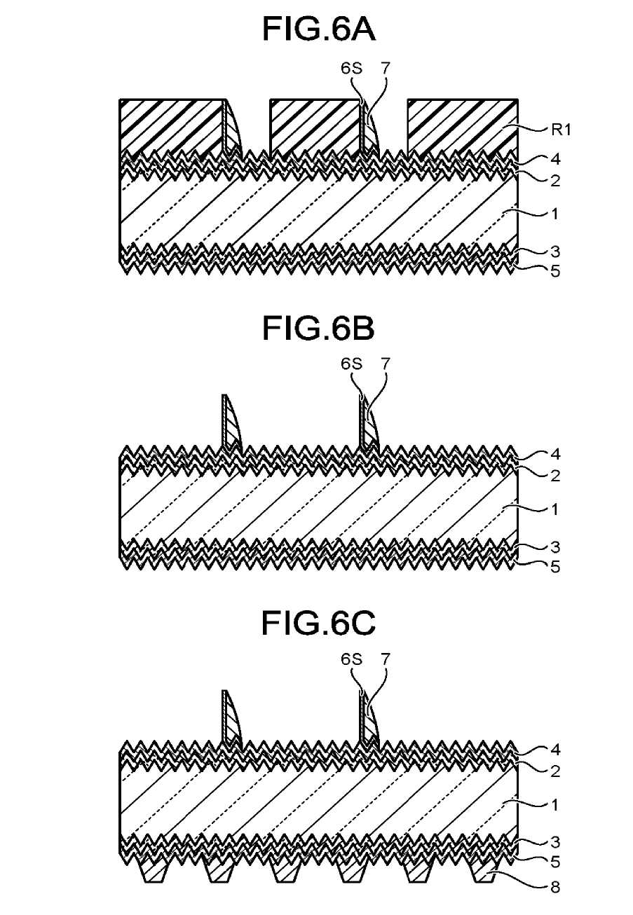

Next, as illustrated in FIG. 6A, selective etching of the seed layer 6S (detachment of seed layer: at S111) is performed using a plated layer pattern that constitutes the grid electrode 7 as a mask, and thereafter resist detachment is performed (removal of resist: at S112). As a selective etching solution for the seed layer 6S, a mixed solution of phosphoric acid, nitric acid, and acetic acid, for example, is used when the seed layer 6S is made of silver seed, or a mixed solution of nitric acid and a hydrogen peroxide solution is used when the seed layer 6S is made of copper seed. FIG. 6B illustrates a cross section of a substrate obtained by this resist detachment.

Next, the back-surface electrode 8 and the bus electrode 10 are screen-printed using thermosetting silver paste (at S113 and S114), and they are then hardened at 200° C. (FIG. 6C). Further, by cutting an unnecessary portion of the substrate edge, formation of the heterojunction solar cell illustrated in FIG. 1 and FIGS. 2A and 2B is finished.

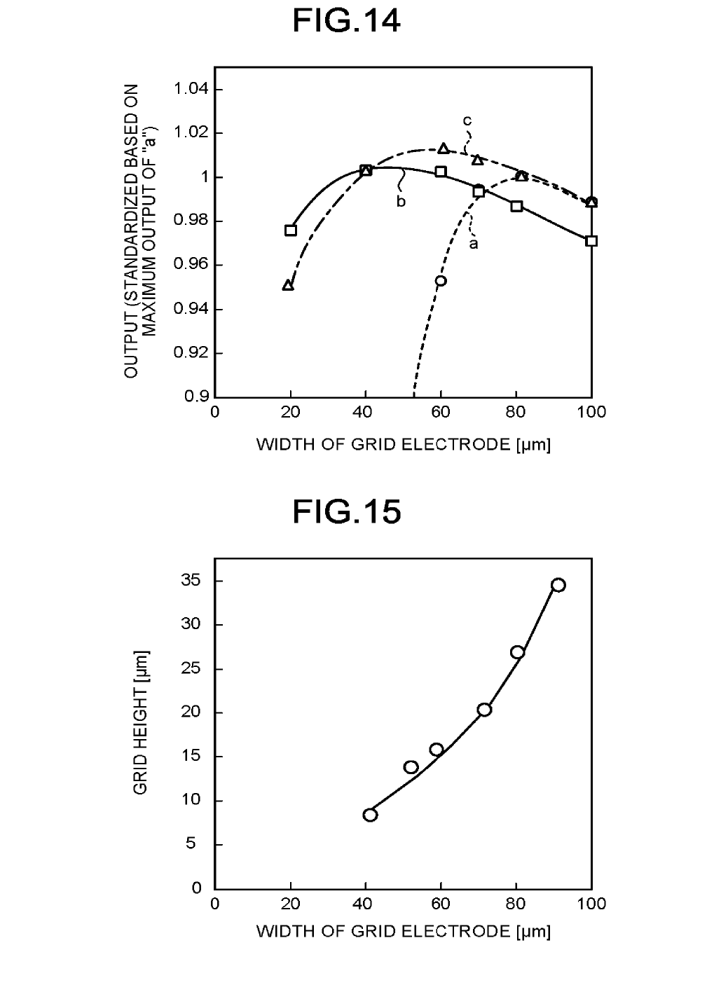

FIG. 14 is a comparative diagram of an output of a solar cell when the width of the grid electrode 7 is changed. The horizontal axis represents the width of a grid electrode. The vertical axis represents the output. The output is standardized as 1 by defining an output in a conventional example in which printing silver is used to form an electrode. A curved line “a” represents an output obtained by using printing silver to form an electrode. A curved line “b” represents an output obtained by using a photomechanical technique and a plating technique. A curved line “c” represents an output of the solar cell according to the first embodiment. The output of the solar cell is standardized on the basis of the maximum output illustrated on the curved line “a”, and the electrode height is maintained at a uniform height of 40 μm for the curved line “b” and the curved line “c”. Referring to the curved line “a”, the maximum output is obtained when the line width is 80 μm, and then as the width of the grid electrode is reduced, the output of the solar cell is significantly decreased. This is because, as a printing-silver electrode is thinned, the height of the grid electrode 7 is simultaneously decreased as illustrated in FIG. 15, which reduces the fill factor to a larger extent.

Next, in a solar-battery cell using a photomechanical technique and a plating technique illustrated by the curved line “b”, the electrode height is 40 μm; therefore, the fill factor tends not to be reduced easily even when the electrode is thinned; and the maximum output is obtained when the grid line-width is 40 μm. However, because the electrode has a rectangular shape, a greater reflection loss occurs on the upper portion of the electrode, so the output of the solar cell is only improved by 0.3% as compared to the curved line “a”.

In contrast, in the solar-battery cell according to the first embodiment illustrated by the curved line “c”, not only is the fill factor reduced to a lesser extent when the electrode is made thin because the electrode has a height of 40 μm, but also low light-shielding loss occurs on the electrode because the electrode has a right angled triangle shape. The maximum output is obtained when the line width is 60 μm. In that specification, the output is improved by 1.3% as compared to the curved line “a”.

As described above, according to the first embodiment, a seed layer that becomes a plated electrode is formed by being deposited not only from the bottom of a resist opening but also from the side surface of the opening. This greatly facilitates formation of an electrode with a high aspect ratio. A plated layer pattern with an inclined surface on one side is formed, which cannot be made by a general photomechanical technique and plating technique. Accordingly, light that is incident on the upper portion of the electrode can also contribute to the power generation, and thus the power generation amount in the solar cell is increased. In the embodiment, a plated layer pattern can be formed with a right-triangular shape in cross section in which when the surface in contact with a substrate is defined as a bottom and the vertex angle apart from the bottom is equal to or smaller than 45 degrees, that is, the ratio of the height to the bottom is equal to or greater than 1.

That is, given that the side on the bottom that is the surface in contact with a substrate is defined as a first side; the side that is substantially vertical to the first side is defined as a second side; and the oblique side that is inclined on one side is defined as a third side, it is desirable to have a right-angled-triangular shape in cross section, in which the vertex angle facing the first side is equal to or smaller than 45 degrees and more desirably, equal to or smaller than 15 degrees. By setting the vertex angle to 45 degrees or smaller, the aspect ratio can be equal to or greater than 1. By setting the vertex angle to 15 degrees or smaller, the aspect ratio can be equal to or greater than 3.7. It is possible to form a low-resistance plated layer pattern with a low light-shielding loss. In the right-angled-triangular shape in cross section, each side can be slanted or deformed. It is adequate that the right-angled-triangular shape in cross section forms a plated layer pattern with a high aspect ratio that is basically equal to or greater than 1.

As described above, in the solar cell according to the first embodiment, a grid electrode is configured by a first seed surface that comes into contact with the light receiving surface of a solar-battery cell; a second seed surface that extends upright from the first seed surface and that is connected to the first seed surface; and a plated layer that comes into contact with the first and second seed surfaces. Therefore, a high-aspect-ratio electrode can be formed, and a low-resistance grid electrode with a low light-shielding loss can be obtained.

A surface of the plated layer in contact with the second seed surface is vertical to the light receiving surface. The plated layer includes an inclined surface on its one side-surface. Therefore, a low-resistance grid electrode with a low light-shielding loss can be obtained. The term “vertical” herein is taken to mean “substantially vertical”. It is taken to mean that the surface of the plated layer in contact with the second seed layer forms an angle of approximately 90 degrees relative to the light receiving surface.

The second seed surface stands upright in the direction normal to the first seed surface, and the first and second seed surfaces have an L shape in cross section. Therefore, a low-resistance grid electrode with a low light-shielding loss can be made. Similarly, the L shape in cross section is not necessarily an exact L shape.

Because the plated layer has grown from the first and second seed surfaces and is oriented to the first and second seed surfaces, it is possible to obtain an electrode with a good quality film and a lower specific resistance.

### Second Embodiment

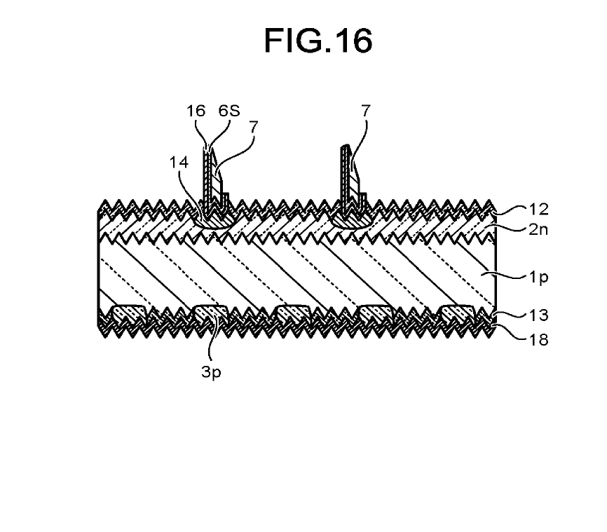

In the first embodiment described above, the thin-film solar cell has been described. However, the solar cell according to a second embodiment of the present invention is a diffusive solar-battery cell in which a pn junction is formed by diffusion. There are differences between the first embodiment and the second embodiment in the process of the method for making contact with an underlying substrate. FIG. 16 is a cross-sectional view schematically illustrating the configuration of a solar cell according to the second embodiment of the present invention. In the solar cell according to the second embodiment, a semiconductor substrate has a first conductivity type; and on the surface of the substrate, an irregular structure, referred to as “texture”, is formed. An n-type diffusion layer 2n is formed as a second-conductivity-type impurity diffusion layer on the light-receiving-surface side of a p-type single-crystal silicon substrate 1p used as the semiconductor substrate. On the top of the n-type diffusion layer 2n, an anti-reflective film 12 and the grid electrode 7 are stacked in the order they appear in this sentence. The anti-reflective film 12 has an opening below the grid electrode 7. Between the grid electrode 7 and the n-type diffusion layer 2n, the seed layer 6S, a barrier metal layer 16, and a silicide layer 14 are interposed.

On the back-surface side, a passivation film 13 and an aluminum electrode 18 are stacked. On the aluminum electrode 18, aluminum is diffused by laser firing to form a BSF layer 3p, and therefore the aluminum electrode 18 is able to conduct with the p-type single-crystal silicon substrate 1p with a first conductivity type. Light, to be photoelectrically converted, is incident on this solar cell from the side of a crystal silicon substrate, on which the n-type diffusion layer 2n that is the second-conductivity-type impurity diffusion layer is formed, i.e., incident thereon from the light-receiving-surface side.

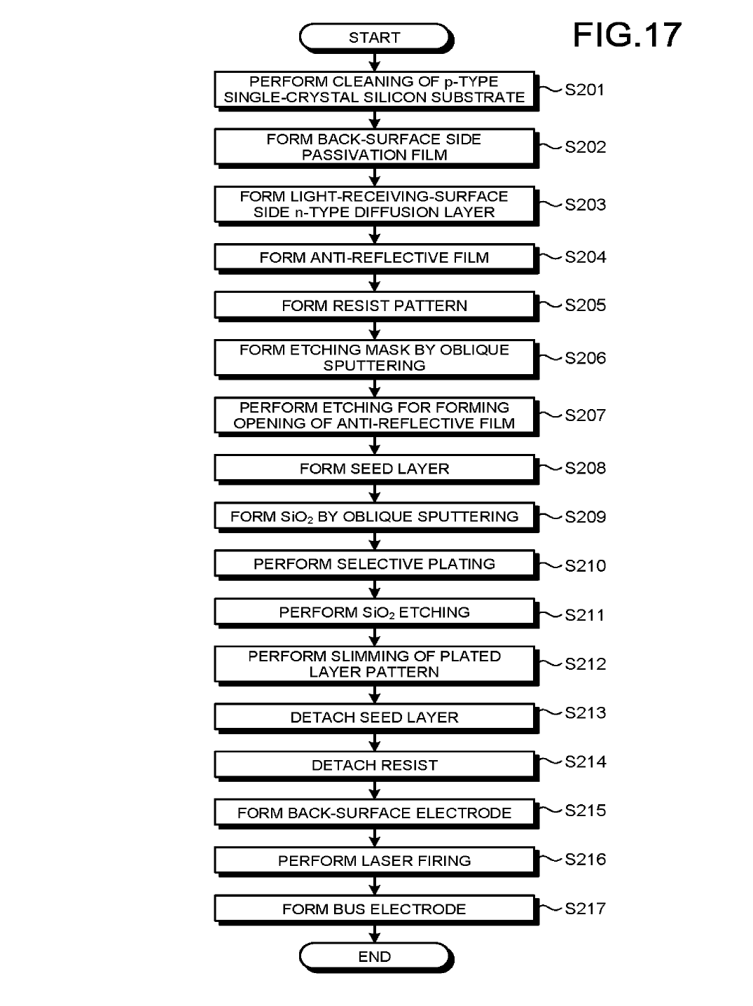

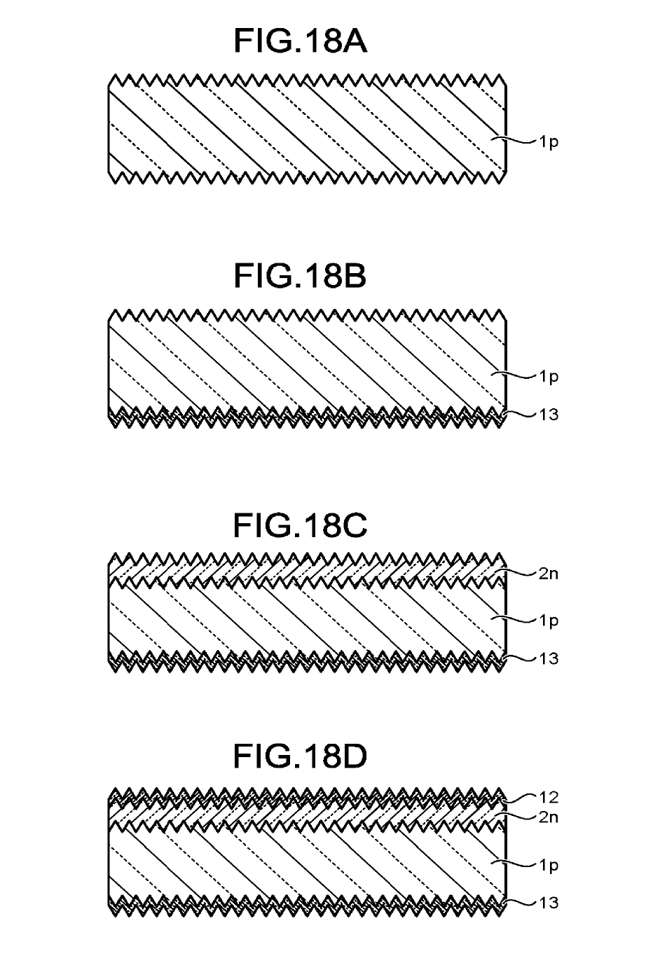

A manufacturing method for the solar cell according to the second embodiment is described below with reference to the accompanying drawings. FIG. 17 is a flowchart for describing an example of manufacturing steps of the solar cell according to the second embodiment of the present invention. FIGS. 18A to 18D, FIGS. 19A to 19C, FIGS. 20A to 20C, FIGS. 21A to 21C, and FIGS. 22A to 22C are step cross-sectional views for describing an example of the manufacturing steps of the solar cell according to the second embodiment of the present invention.

First, similarly to the case in the first embodiment, a damaged layer is removed from a substrate by cleaning the substrate, and also a surface texture is formed to obtain a textured p-type single-crystal silicon substrate 1p as illustrated in FIG. 18A (at S201). Subsequently, a uniform thickness of the passivation film 13 is formed on the back-surface side of the textured substrate 1p (FIG. 18D: at S202). It is desirable to have a great thickness of the passivation film 13 in advance, taking into consideration that the passivation film 13 is to be etched at a subsequent step. For example, the thickness can be set to approximately 300 nm. The passivation film 13 is formed using a plasma CVD, for example, in which a mixture of silane (SiH₄) gas and ammonia (NH₃) gas is used as a raw material to form a silicon nitride film that serves as the passivation film 13 under conditions of a temperature of 300° C. or higher and at a reduced pressure, for example.

Next, diffusion treatment is performed to form a pn junction on the p-type single-crystal silicon substrate 1p (FIG. 18C: at S203). That is, V-family elements such as phosphorus (P) are diffused onto a semiconductor substrate to form the n-type diffusion layer 2n with a thickness of several hundreds of nanometers. In this example, on the p-type single-crystal silicon substrate 1p formed with a texture structure on its surface, phosphorus is thermally diffused thereonto at a high temperature by a vapor-phase diffusion method within a phosphorus oxychloride (POCl₃) gas so as to form a pn junction. In this manner, a semiconductor substrate is obtained, in which a pn junction is configured by the p-type single-crystal silicon substrate 1p that is a first conductivity-type layer and the n-type diffusion layer 2n that is a second conductivity-type layer formed on the light-receiving-surface side of the p-type single-crystal silicon substrate 1p. It is possible to control the phosphorus concentration to be diffused at this time by adjusting the concentration of the phosphorus oxychloride (POCl₃) gas, the atmosphere temperature, and the heating time. The n-type diffusion layer 2n formed on the surface of the semiconductor substrate has a sheet resistance of 40 Ω/□ to 60 Ω/□, for example.

In this example, on the surface of the n-type diffusion layer 2n immediately after its formation, a glass (phospho-silicate glass (PSG)) layer is formed thereon during the diffusion treatment. Therefore, the PSG layer is removed from the surface using a hydrofluoric acid solution. Note that the back-surface side is protected by a SiN film, so the n-type diffusion layer 2n is not formed.

Next, in order to improve the photoelectric conversion efficiency, on one surface of a semiconductor substrate, which is on the light-receiving-surface side, i.e., on the n-type diffusion layer 2n, the anti-reflective film 12 is formed with a uniform thickness (FIG. 18D: at S204). The thickness and refractive index of the anti-reflective film 12 are set to values that are most effective in reducing light reflection. The anti-reflective film 12 is formed in the same manner as forming a back-surface passivation film. The refractive index is approximately 2.0 to 2.2, for example. The film thickness is approximately 60 nm to 80 nm, for example. Two or more layers of films with different refractive indexes can be stacked as the anti-reflective film 12. As the method for forming the anti-reflective film 12, a plasma CVD method or other methods such as a vapor deposition method or a heat CVD method can be used. It should be noted that the anti-reflective film 12, formed as described above, is an insulator. Only forming a plated layer pattern on this insulator does not make it function as a solar cell.

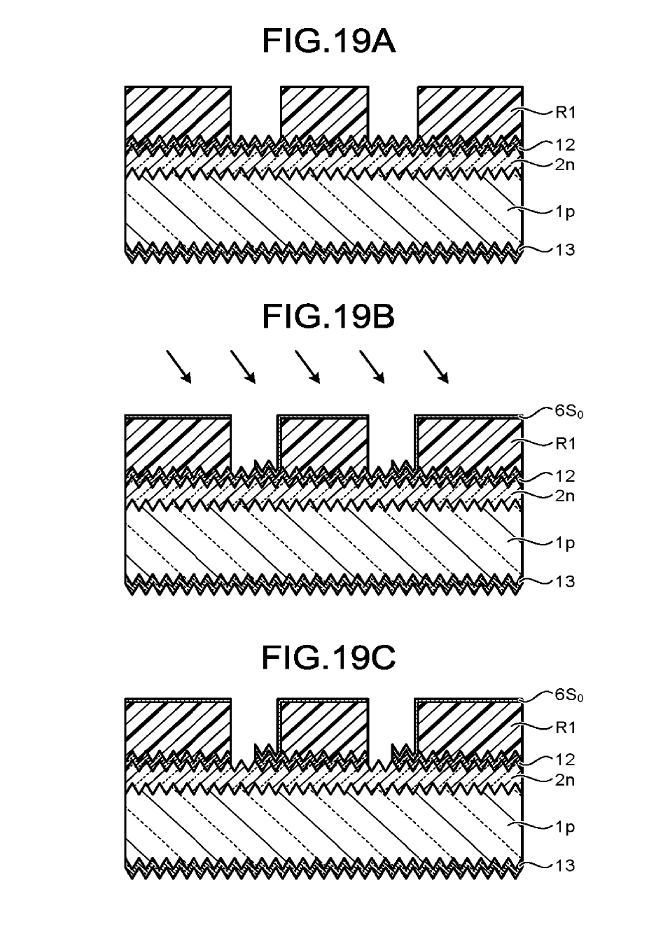

Subsequently, the resist film R1 is spin-coated and its thickness is adjusted to approximately 40 μm, and thereafter exposure and developing treatment is performed to obtain a resist pattern with an opening as illustrated in FIG. 19A (at S205). Next, as illustrated in FIG. 19B, an etching mask 6S₀ made of metal that is resistant to heated phosphoric acid is formed by using a DC magnetron sputtering method, for example, under conditions of incidence from an oblique direction to the substrate (at S206). Examples of the material of the etching mask 6S₀ include silver, platinum, and gold. The substrate angle θ at this time is obtained by the expression (1) described above. It is adequate that the etching mask 6S₀, made of metal that is resistant to heated phosphoric acid, is thick enough to serve as a mask member when the heated phosphoric acid treatment is performed, and therefore has a thickness of approximately 50 nm. FIG. 19C illustrates a cross-sectional view of a substrate obtained after the heated phosphoric acid treatment (at S207: etching for forming opening of anti-reflective film). The anti-reflective film obtains an opening with a width smaller than the resist-opening width. It is satisfactory that this etching mask 6S₀, also referred to as “lower-layer-side seed layer”, serves as a mask layer when an opening is formed on the anti-reflective film. The etching mask 6S₀ can be made of a material different from the seed layer 6S. For example, the etching mask 6S₀ can be configured by a layer of another kind of metal, or it can be configured by a mask layer constituted by a silicon oxide layer or other layer in the case where the anti-reflective film 12 is made of silicon nitrogen.

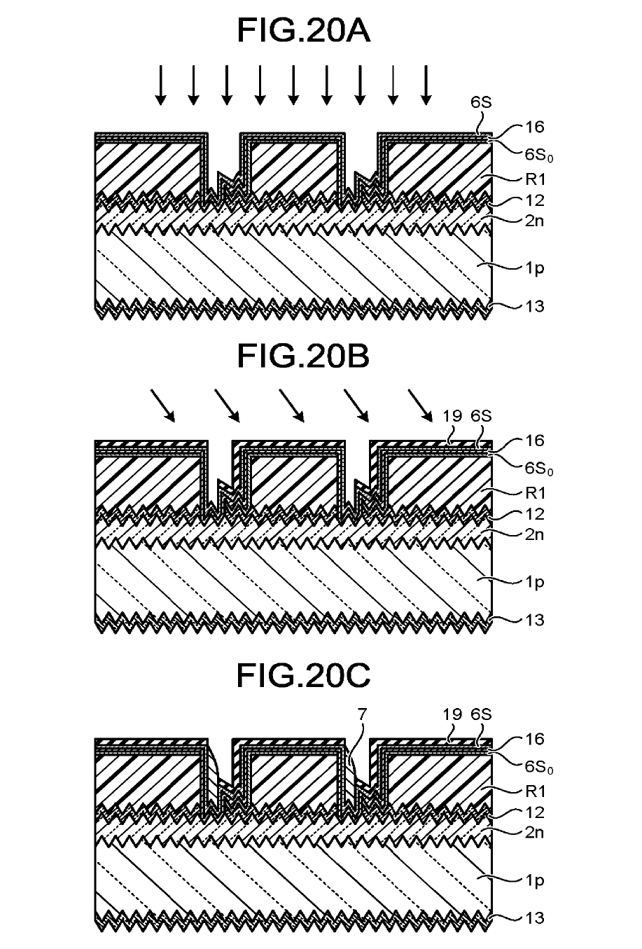

Subsequently, as illustrated in FIG. 20A, the barrier metal layer 16 is formed on the substrate from above, and successively the seed layer 6S is formed through this barrier metal layer 16 (formation of seed layer: at S208). It is preferable for a barrier layer to be made of a material that not only provides improved barrier performance against copper but also offers a low contact resistance. For example, Ni, Ti, Co, or W can be used. Next, as illustrated in FIG. 20B, an insulating film 19 is formed from an oblique direction to the substrate (oblique sputtering: at S209) to form a pattern of the insulating film 19 such that the seed layer 6S is exposed only on the side surface and lower portion of a resist opening. The substrate angle at this time is set on the bases of the expression (1) described above. It is preferable for an insulating film to be made of a material such as SiO₂, TiO₂, or Al₂O₃. The insulating film has a sufficient thickness equal to or greater than 50 nm.

Next, plating treatment is performed by using a plating device illustrated in FIG. 12 (at S210) to obtain the grid electrode 7 that has a high aspect ratio and a right-triangular shape. FIG. 20C illustrates a cross-sectional view of a substrate obtained by this treatment.

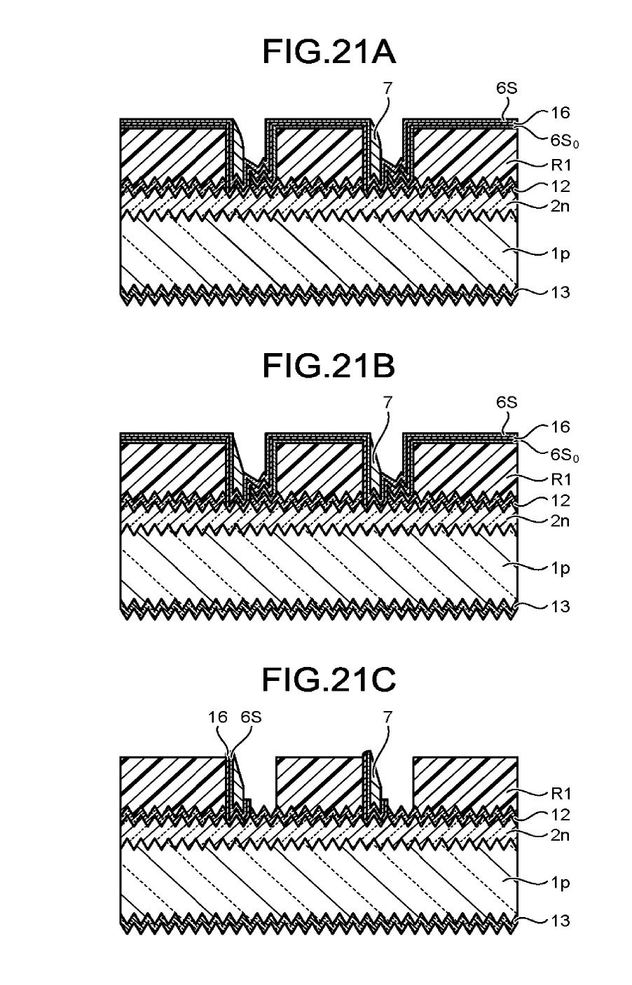

Next, as illustrated in FIG. 21A, the insulating film 19 is removed from the substrate 1 by hydrofluoric acid treatment (S211), and thereafter the substrate 1 is soaked in a copper selective etching solution. Therefore, the grid electrode 7 that is a plated layer pattern can further be thinned (slimming of plated layer pattern: at S212). In this manner, effective utilization of light that is incident to an electrode and a reduction in wire resistance can both be achieved. FIG. 21D illustrates a cross-sectional view of a substrate obtained at this treatment.

Next, as illustrated in FIG. 21C, etching is performed on the seed layer 6S, the barrier metal layer 16, and the etching mask 6S₀ (detachment of seed layer: at S213). Dilute sulfuric acid, or a mixed solution of phosphoric acid, nitric acid, and acetic acid is used for etching. At this time, the grid electrode 7 constituted by a plated layer pattern is thicker than the seed layer 6S, the etching mask 6S₀, and the barrier metal layer 16. Therefore, the shape of the plated layer pattern hardly changes after etching.

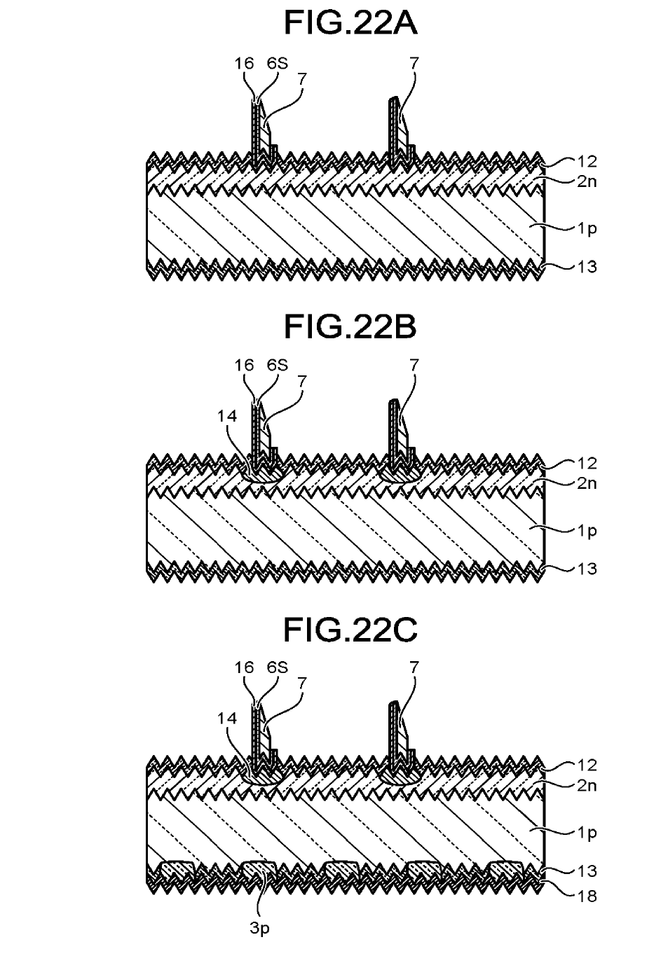

Next, as illustrated in FIG. 22A, a resist is detached (at S214), and thereafter by performing heat treatment in a vacuum at the temperature of around 400° C., barrier metal and silicon are alloyed with each other so as to form the silicide layer 14 below the grid electrode 7. FIG. 22B illustrates this silicide layer 14, by which a low contact resistance can be obtained even in the case where the grid electrode 7 is made thin.

Subsequently, an aluminum electrode is evaporated on the back surface (S215), and laser firing is performed partially on the aluminum electrode to obtain a point contact structure (at S216). Lastly, the bus electrode 10 is screen-printed by using thermosetting silver paste (at S217), and is hardened at the temperature of 200° C. Also, by cutting an unnecessary portion of the substrate edge, a plan view are obtained for a substrate, which is the same as illustrated in FIG. 2B and a cross-sectional view of the substrate illustrated in FIG. 22C. Formation of the diffusive solar-battery cell is then finished.

While in the first and second embodiments described above, a grid electrode is formed so as to have an inclined surface along its extending direction, the grid electrode can be formed with irregularities in a manner such as forming notches in a direction crossing the extending direction. By forming irregularities in a direction crossing the extending direction as described above, particularly at the intersection between the grid electrode and the bus electrode, the irregularities induce diffusion light and therefore guide obliquely-directed light to a photoelectric conversion unit that is immediately below the intersection. This can increase the photoelectric conversion efficiency.

At the plating step in the first and second embodiments described above, because the seed layer 6S is formed on the entire surface of a substrate, electric field distribution hardly appears when plating. Because a substrate-exposed portion when forming the seed layer 6S is limited only to a resist opening, plasma damages to the substrate can be avoided.

In the first and second embodiments described above, an insulating film is formed from an oblique direction to expose the seed layer 6S only on the side surface and lower portion of a resist opening, from which a plated coating is grown in a lateral direction. Therefore, a plated layer is deposited not only from the bottom of the resist opening but also from the side surface of the opening. This not only greatly facilitates formation of a high-aspect-ratio electrode but also increases the plating speed.

In the step of forming an insulating film, the line width of a grid electrode can be adjusted by adjusting the bottom line-width of the grid electrode, while adjusting the inclination angle at which a substrate is inclined relative to a sputtering direction.

Further, at the plating step, it is desirable to control the plating time so as to continue plating until the upper line-width of a grid electrode reaches a desired value. With this operation, the occurrence of breakage of a thinned wire is reduced, and the yield ratio is improved.

Note that in the first and second embodiments described above, a p-type single-crystal silicon substrate is used as a substrate; it is also possible to use other crystal-system semiconductor substrates usable for a solar cell, such as a p-type polycrystalline silicon substrate, an n-type single-crystal silicon substrate, an n-type polycrystalline silicon substrate, and a SiGe semiconductor substrate. While in the second embodiment described above, a pn junction is formed by forming an n-type diffusion layer on the light-receiving-surface side, it is apparent that an n-type diffusion layer can be formed instead on the back-surface side. In that case, it is desirable to appropriately select an electrode material, a seed material, a barrier material, and other materials in accordance with the polarity immediately below the electrode.

A bus electrode is not necessarily formed by a plated layer pattern. It is possible to connect an interconnector directly on a grid electrode in a direction perpendicular to the grid electrode so as to achieve an external connection. In either case, the light-shielding area that is caused by a grid electrode can be reduced, and therefore the light receiving area can be increased. This makes it possible to provide a solar cell with high photoelectric conversion efficiency.

Furthermore, in the first and second embodiments described above, a sealing member of a solar cell has not been described. However, it is desirable to further provide a translucent surface member so as to cover the light receiving surface of a solar-battery cell, and provide a sealing member between the translucent surface member and the light receiving surface of the solar-battery cell. In this manner, a high-aspect-ratio grid electrode is also protected by the sealing member, and the diffusion on the interface between the grid electrode and the sealing member increases the light receiving amount. This makes it possible to achieve improvement in photoelectric conversion efficiency.

### Third Embodiment

While in the second embodiment described above, the diffusive solar cell using a p-type substrate has been described, a solar cell according to a third embodiment of the present invention is a diffusive solar cell using an n-type substrate. There are differences between the second embodiment and the third embodiment in the process of a method for forming a diffusion layer or a method for forming a passivation layer.

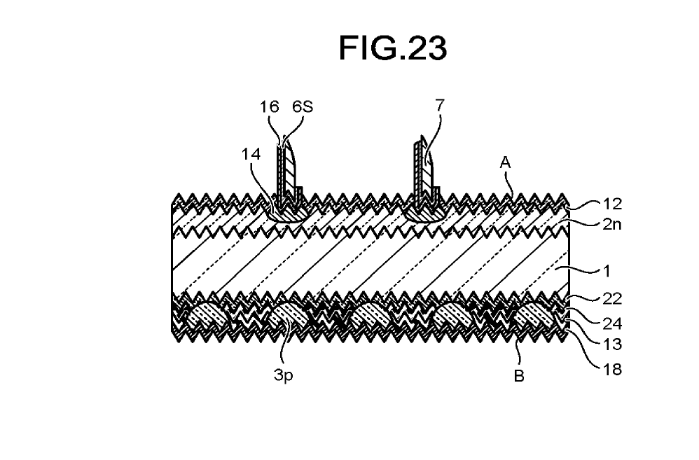

FIG. 23 is a cross-sectional view schematically illustrating the configuration of a solar cell according to the third embodiment of the present invention. In the solar cell according to the third embodiment, a semiconductor substrate has a first conductivity type; and on the substrate surface, an irregular structure, referred to as “texture”, is formed. The n-type diffusion layer 2n is formed as a first-conductivity-type high-concentration impurity diffusion layer on the side of the light receiving surface A of an n-type single-crystal silicon substrate 1. On the top of the n-type diffusion layer 2n, the anti-reflective film 12 and the grid electrode 7 are stacked in the order they appear in this sentence. The anti-reflective film 12 is opened below the grid electrode 7. Between the grid electrode 7 and the n-type diffusion layer 2n, the seed layer 6S, the barrier metal layer 16, and the silicide layer 14 are interposed.

On the side of the back surface B, a p-type diffusion layer 22 with a second conductivity type is formed; and further an alumina (Al₂O₃) film 24, the passivation film 13, and the aluminum electrode 18 are stacked in the this order. On the aluminum electrode 18, aluminum is diffused by laser firing to form the BSF layer 3p, and therefore the aluminum electrode 18 is brought into conduction with the p-type diffusion layer 22 with a second conductivity type. In the solar cell according to the third embodiment, light, which is to be photoelectrically converted, is incident from a side of a crystal silicon substrate, on which the n-type diffusion layer 2n that is the first-conductivity-type high-concentration impurity diffusion layer is formed, that is, incident from the side of the light receiving surface A.

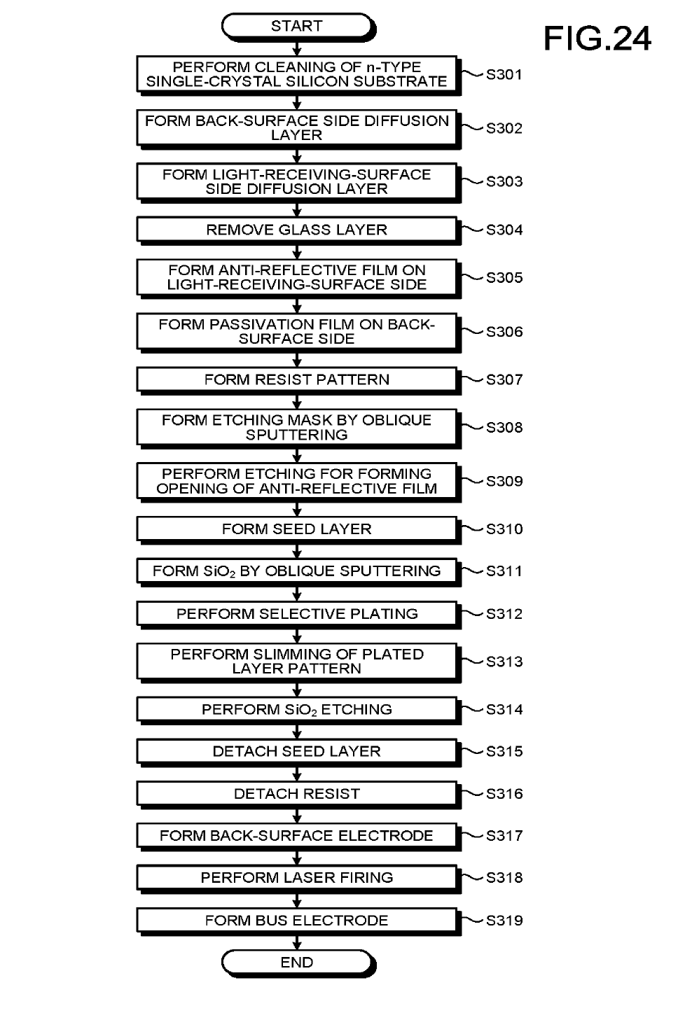

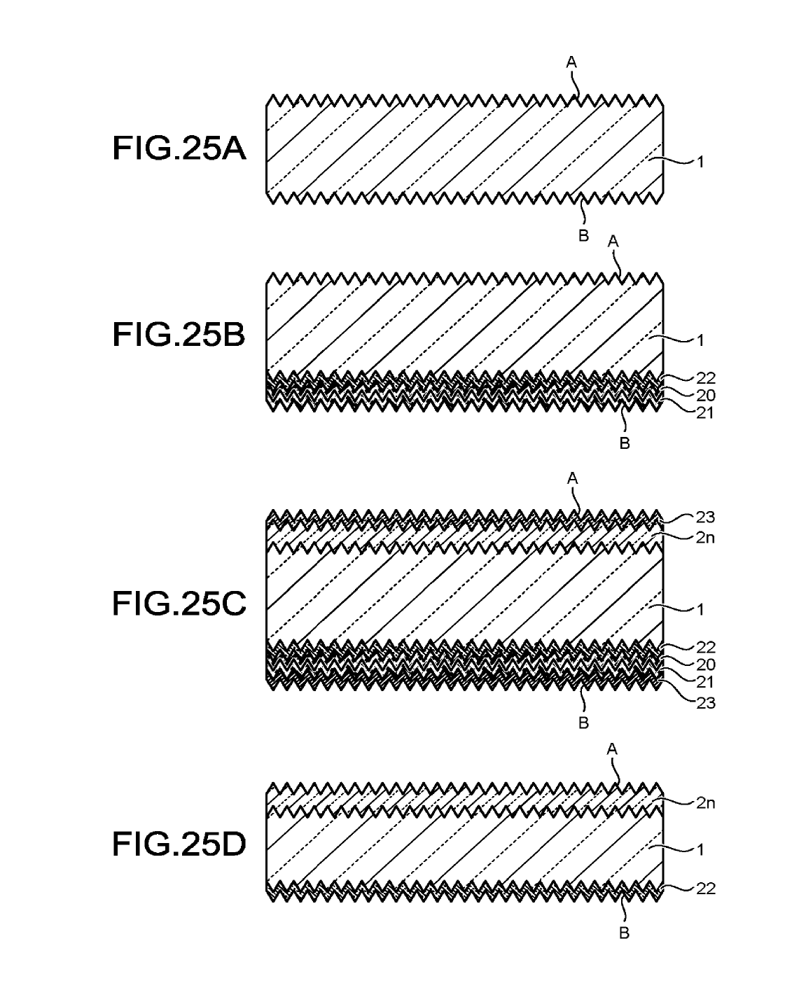

A manufacturing method for the solar cell according to the third embodiment is described below with reference to the accompanying drawings. FIG. 24 is a flowchart for describing an example of manufacturing steps of the solar cell according to the third embodiment of the present invention. FIGS. 25A to 25D, FIGS. 26A to 26D, FIGS. 27A to 27C, FIGS. 28A to 28C, FIGS. 29A to 29C, and FIGS. 30A to 30C are step cross-sectional views for describing an example of the manufacturing steps of the solar cell according to the third embodiment of the present invention. In the third embodiment, a pn junction is formed on the side of the back surface B.

First, similarly to the case in the second embodiment, a damaged layer is removed from a substrate by cleaning the substrate, and also a surface texture is formed to obtain a textured n-type single-crystal silicon substrate 1 as illustrated in FIG. 25A (at S301). Subsequently, on the side of the back surface B of the textured substrate 1, a borosilicate glass layer that is a BSG layer 20 and a non-doped silicate glass layer that is an NSG layer 21 are formed using a CVD method capable of forming a film only on one side. At this forming, the NSG layer 21 formed on the BSG layer 20 has a function of preventing boron from moving to the side of the light receiving surface A, due to the diffusion of boron at the heat treatment. It suffices that each of the BSG layer 20 and the NSG layer 21 has a thickness of approximately 100 nm.

Subsequent to the above film-forming treatment of the BSG layer 20 and the NSG layer 21, heat treatment is performed on a substrate to diffuse boron on the side of the back surface B of the substrate so as to form the p-type diffusion layer 22 that is a back-surface side diffusion layer, as illustrated in FIG. 25B (at S302). In this manner, a semiconductor substrate is obtained, in which a pn junction is configured by the n-type single-crystal silicon substrate 1 that is a first conductivity-type layer and the p-type diffusion layer 22 that is a second conductivity-type layer formed on the side of the back surface B of the n-type single-crystal silicon substrate 1.

Subsequently, an oxide film on the side of the light receiving surface A is removed by applying the hydrofluoric acid treatment, and thereafter V-family elements such as phosphorus (P) are diffused on the semiconductor substrate so as to form the n-type diffusion layer 2n with a thickness of several hundreds of nanometers, which is a light-receiving-surface side diffusion layer as illustrated in FIG. 25C (at S303). In this example, on the n-type single-crystal silicon substrate 1 formed with a texture structure on its surface, phosphorus is thermally diffused at high temperature by a vapor-phase diffusion method in a phosphorus oxychloride (POCl₃) gas atmosphere so as to form the n-type diffusion layer 2n. It is possible to control the phosphorus concentration obtained by diffusion at this treatment by adjusting the concentration of the phosphorus oxychloride (POCl₃) gas, the atmosphere temperature, and the heating time. The n-type diffusion layer 2n formed on the surface of the semiconductor substrate has a sheet resistance, for example, equal to or higher than 40 Ω/□ and equal to or lower than 100 Ω/□.

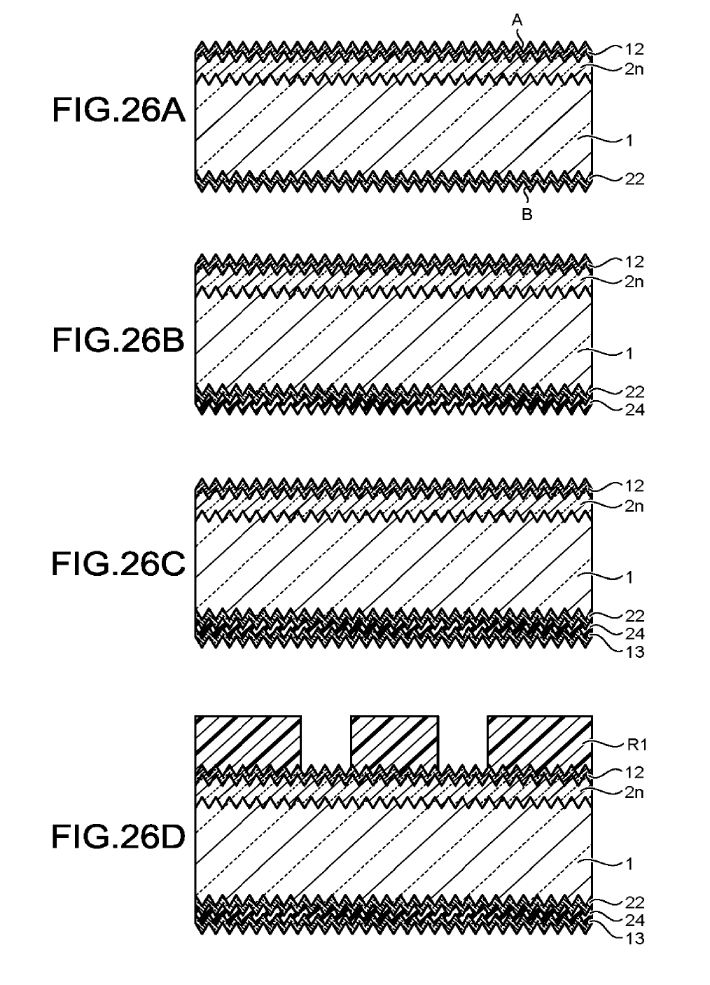

Next, a glass layer constituted by the BSG layer 20, the NSG layer 21, and a PSG layer 23, which have been formed at the diffusion-layer forming step, is removed by using an etching solution such as a hydrofluoric acid solution as illustrated in FIG. 25D (at S304). Thereafter, in order to improve the photoelectric conversion efficiency, the anti-reflective film 12 is formed with a uniform thickness as illustrated in FIG. 26A on one surface of a semiconductor substrate, which is on the side of the light receiving surface A, that is, on the n-type diffusion layer 2n (at S305). The thickness and refractive index of the anti-reflective film 12 are set, for example, to values that reduce light reflection to the maximum. A refractive index “n” of the anti-reflective film 12 is approximately 2.0≦n≦2.2. A thickness “t” of the anti-reflective film 12 is, for example, approximately 60 nm≦t≦80 nm. Two or more layers of films with different refractive indexes can be stacked as the anti-reflective film 12. As the method for forming the anti-reflective film 12, a plasma CVD method or other film forming methods such as a vapor deposition method or a heat CVD method can be used. It should be noted that the anti-reflective film 12, formed as described above, is an insulator. Only providing a plated layer pattern on this insulator does not make it function as a solar cell.

Subsequently, as illustrated in FIG. 26B, the alumina film 24 is formed on the side of the back surface B of the substrate in order to improve passivation performance. An atomic layer deposition (ALD) method capable of forming a film only on one side, a CVD method, and a sputtering method are suitable for an alumina-film forming method. An alumina film has a high-density negative fixed charge, and therefore has high passivation ability for a p-type diffusion layer, thereby contributing mainly to improvement in Jsc and Voc. As the passivation film 13, an alumina film or other films of silicon oxide (SiO₂) or titanium oxide (TiO₂), for example, can be used.

Further, as illustrated in FIG. 26C, after the alumina film 24 is formed, the passivation film 13 is stacked on the alumina film 24 (at S306). A silicon nitride film is suitable for the passivation film 13. It is desirable to set a greater thickness of the passivation film 13 in advance, taking into consideration that the passivation film 13 is to be etched at a subsequent step. The thickness can be set to approximately 300 nm. The silicon nitride film is formed by using a plasma CVD method. A mixture of silane (SiH₄) gas and ammonia (NH₃) gas is used as a raw material to form the silicon nitride film under the conditions of the temperature of 300° C. or higher and a reduced pressure. The film thickness and film forming method described above are merely an example, and the passivation film 13 is not limited thereto. The passivation film 13 constituted by the silicon nitride film is stacked on the alumina film 24 in the manner as described above. Therefore, not only the firing resistance is enhanced but also a higher passivation effect can be obtained by the influence of hydrogen contained in silicon nitride.

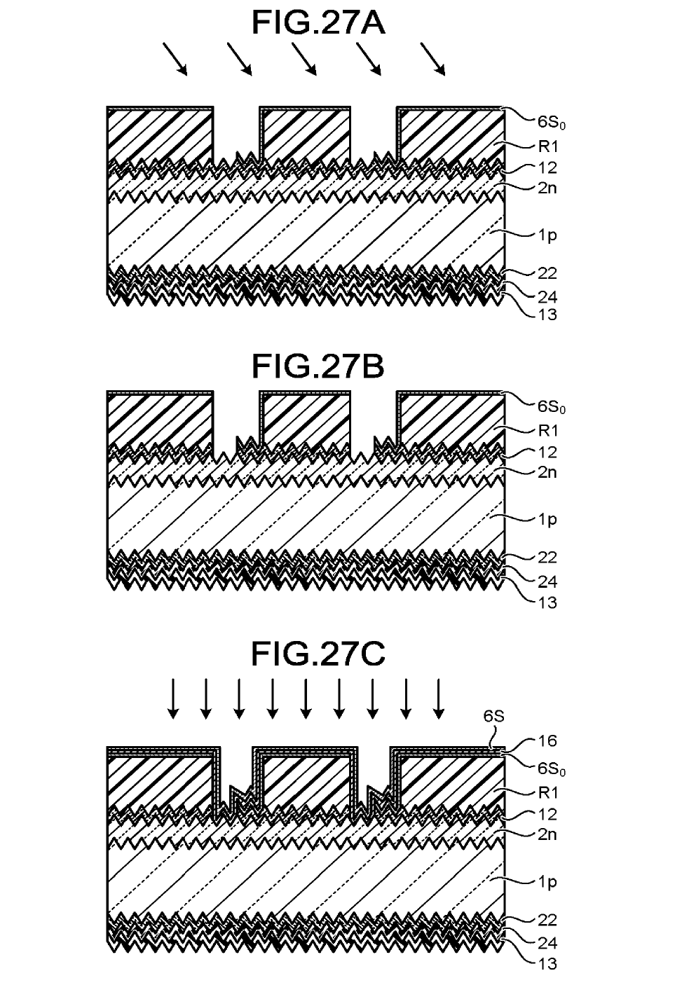

Subsequently, the resist film R1 is spin-coated and its thickness is adjusted to approximately 40 μm, and thereafter exposure and developing treatment is performed so as to obtain a resist pattern with an opening as illustrated in FIG. 26D (at S307). Next, as illustrated in FIG. 27A, the etching mask 6S₀ is formed by oblique sputtering (S308). In this example, the etching mask 6S₀, made of metal that is resistant to heated phosphoric acid, is formed using a DC magnetron sputtering method under a condition of the incidence from an oblique direction to the substrate. As a material of the etching mask 6S₀, metal such as silver, platinum, or gold is used. The substrate angle θ at this treatment is obtained by the expression (1) described above. It is enough that the etching mask 6S₀, made of metal that is resistant to hydrofluoric acid, is thick enough to serve as a mask member during the heated phosphoric acid treatment, and therefore appropriately has a thickness of approximately 50 nm. FIG. 27B illustrates a cross-sectional view of a substrate obtained after the heated phosphoric acid treatment (etching for forming openings of anti-reflective film: at S309). The anti-reflective film is provided with an opening with a width smaller than the resist-opening width. It is enough that the etching mask 6S₀ serves as a mask layer when an opening is formed on the anti-reflective film 12. The etching mask 6S₀ can be made of a material different from the seed layer 6S. When the anti-reflective film 12 is made of silicon nitride, a mask layer constituted by a silicon oxide layer can be used, or a mask layer constituted by a layer of different kind of metal can also be used.

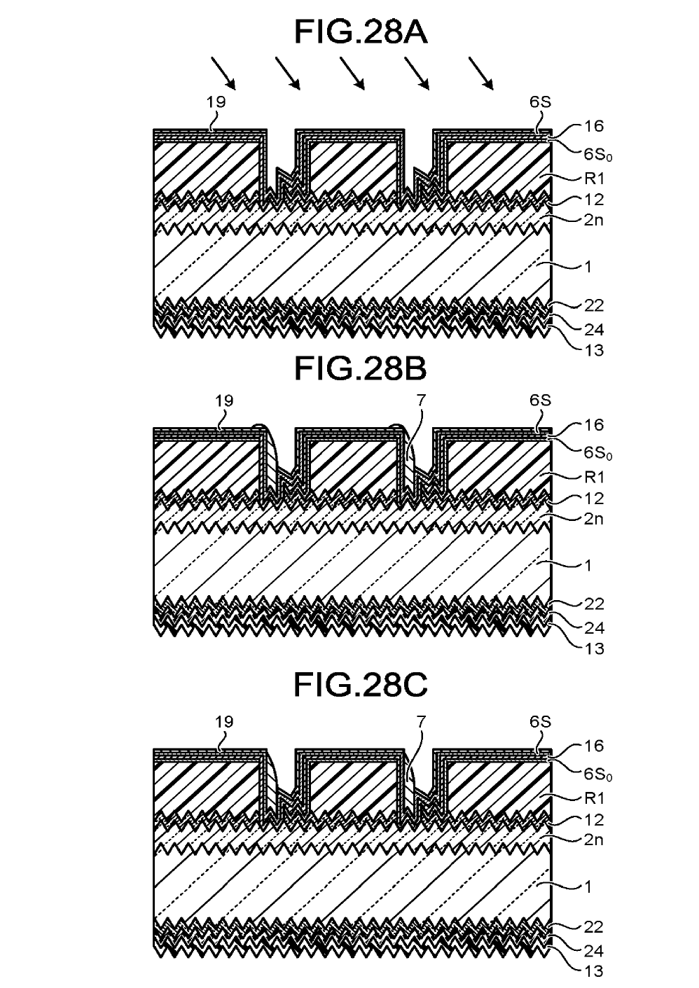

Subsequently, as illustrated in FIG. 27C, the barrier metal layer 16 and the seed layer 6S are formed successively on the substrate from above (formation of seed layer: at S310). It is preferable for a barrier layer to be made of a material that not only provides improved barrier performance against copper but also obtains a lower contact resistance. For example, metal such as Ni, Ti, Co, or W can be used for the barrier layer. Next, as illustrated in FIG. 28A, a SiO₂ film is formed as the insulating film 19 from an oblique direction to the substrate (oblique sputtering: at S311) to form a pattern of the insulating film 19 such that the seed layer 6S is exposed only on the side surface and lower portion of a resist opening. The substrate angle θ at this treatment conforms to the expression (1) described above. It is preferable for an insulating film to be made of a material such as SiO₂, TiO₂, or Al₂O₃. It suffices that the insulating film has a thickness equal to or greater than 50 nm.

Next, selective plating treatment is performed by using the plating device illustrated in FIG. 12 (at S312) to obtain the grid electrode 7 with a high aspect ratio and with an inclined surface on one side. FIG. 28B illustrates a cross-sectional view of a substrate obtained at this treatment.

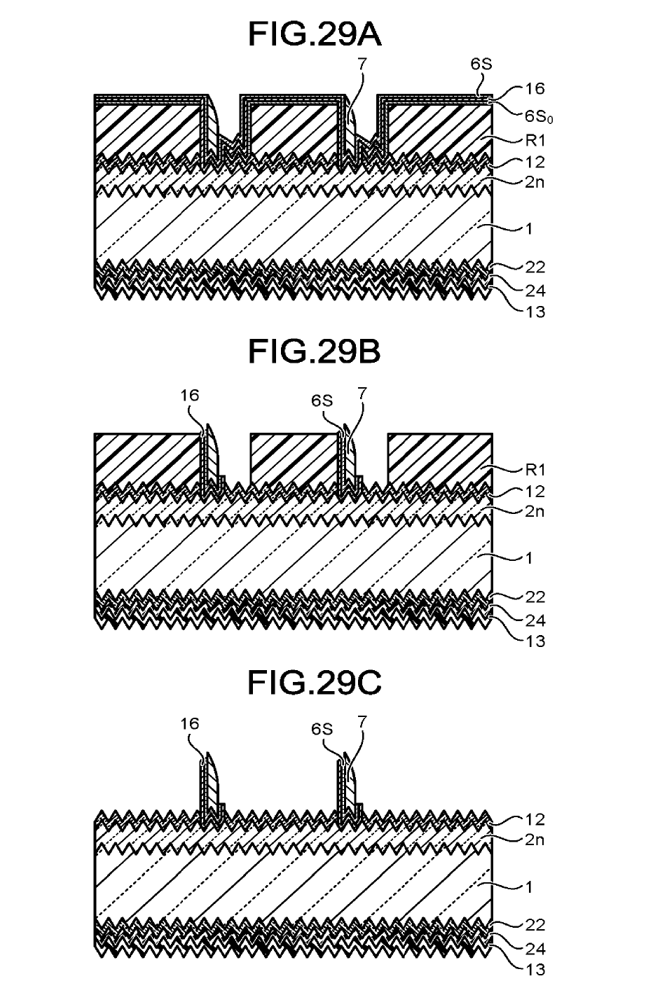

Next, as illustrated in FIG. 28C, by soaking the substrate in a cooper selective etching solution, not only the grid electrodes 7 that is plated layer pattern can be further thinned but also the peak rounded portions of the grid electrode 7 are removed. Therefore, the light-shielding area is decreased (slimming of plated layer pattern: at S313). In this manner, effective utilization of light incident to an electrode and a reduction in wire resistance can both be achieved. Subsequently, a SiO₂ film that is the insulating film 19 is etched by hydrofluoric acid treatment (at S314) so that a substrate with a cross-sectional view illustrated in FIG. 29A, is obtained.

Next, as illustrated in FIG. 29B, etching is performed on the seed layer 6S, the barrier metal layer 16, and the etching mask 6S₀ (detachment of seed layer: at S315). Dilute sulfuric acid, or a mixed solution of phosphoric acid, nitric acid, and acetic acid is used for etching. Here, the grid electrode 7 constituted by a plated layer pattern is thicker than the seed layer 6S, the etching mask 6S₀, and the barrier metal layer 16. Therefore, the shape of the plated layer pattern hardly changes after etching.

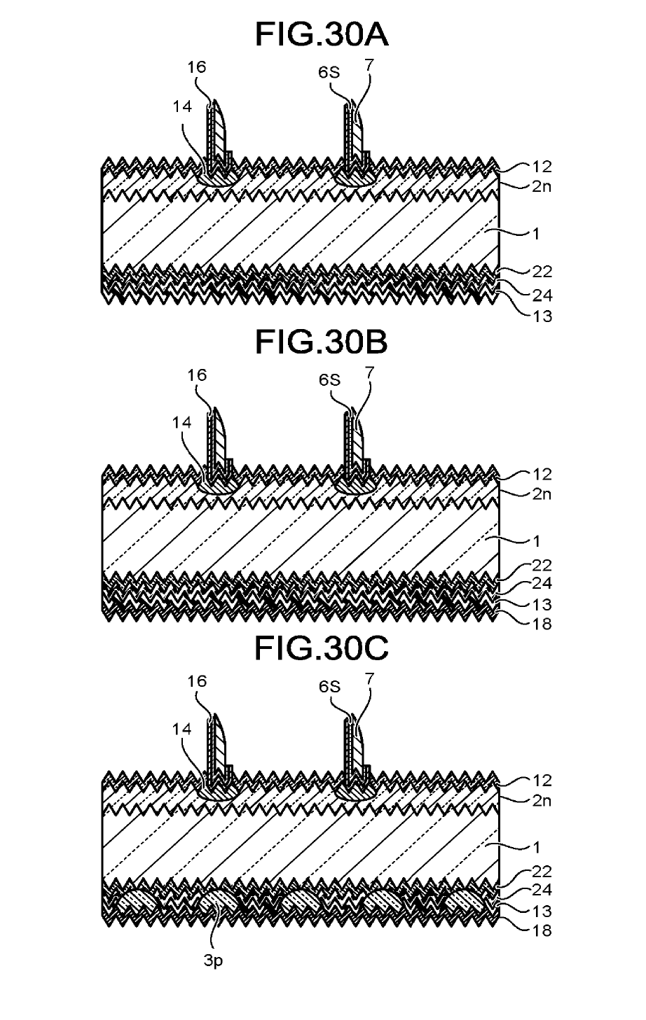

Next, as illustrated in FIG. 29C, a resist is detached (at S316), and thereafter by performing heat treatment in a vacuum at the temperature of around 400° C., barrier metal and silicon are alloyed with each other so as to form the silicide layer 14 below the grid electrode 7. FIG. 30A illustrates this silicide layer 14, by which a low contact resistance can be obtained even when the grid electrode 7 is made thin.

Subsequently, as illustrated in FIG. 30B, a back-surface electrode is formed on the back surface B (at S317). At this step, the aluminum electrode 18 is formed by vapor deposition or aluminum-paste screen printing, and thereafter laser firing (S318) is performed partially on the aluminum electrode 18. Therefore, as illustrated in FIG. 30C, the BSF layer 3p is formed by aluminum diffusion to provide a point contact structure thereon. Lastly, thermosetting silver paste or copper paste is used for screen-printing, and is hardened at the temperature of 200° C. so as to form a bus electrode (at S319). Also, by cutting an unnecessary portion of the substrate edge if any, a solar cell can be obtained that has a substrate with a plan view same as illustrated in FIG. 2B and with a cross-sectional view as illustrated in FIG. 30C. Formation of the n-type diffusion solar-battery cell is then finished.

While in the third embodiment, an n-type single-crystal silicon substrate is used as a substrate, it is also possible to use other crystal-system semiconductor substrates usable for a solar cell, such as an n-type polycrystalline silicon substrate, a p-type single-crystal silicon substrate, a p-type polycrystalline silicon substrate, and a SiGe semiconductor substrate. While in the third embodiment, a pn junction is formed by forming a p-type diffusion layer on the side of the back surface B, it is clear that, conversely, a p-type diffusion layer can be formed on the side of the light receiving surface A. In that case, it is desirable to appropriately select an electrode material, a seed material, and a barrier material according to the polarity immediately below the electrode.

### Fourth Embodiment

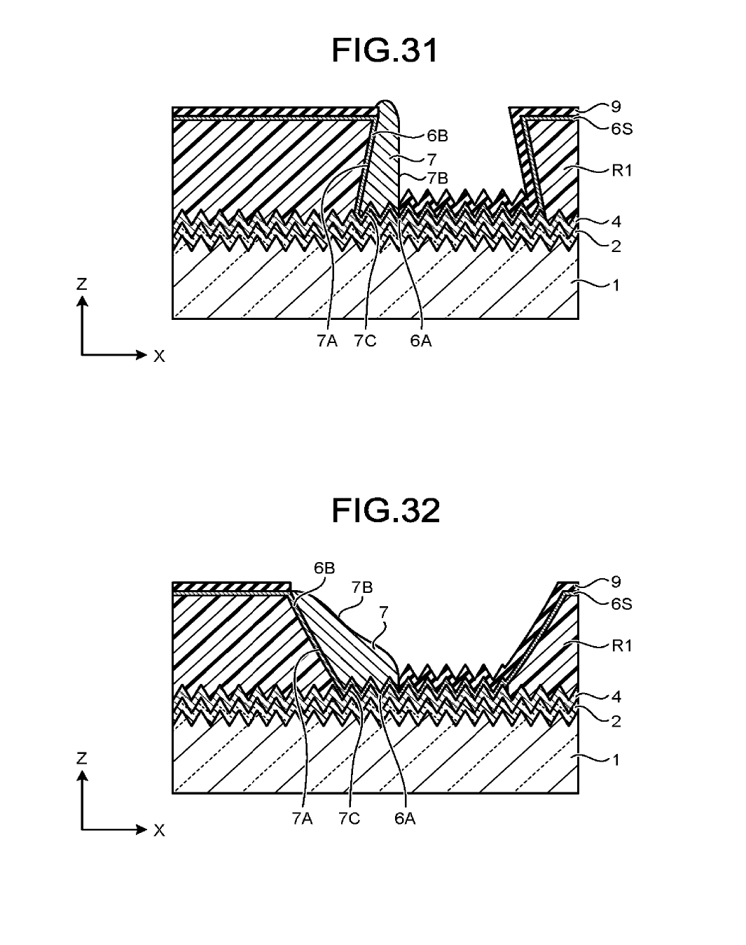

In the first, second, and third embodiments, a grid electrode is made by using a rectangular resist pattern, in which one side-surface of the grid electrode is parallel to the Z-axis. However, it is possible to make various shapes of gird electrodes by controlling the resist-forming conditions. For example, when using a negative resist by which an inversely tapered shape is easily made in principle, it is possible to produce an inversely-tapered resist pattern by adjusting the resist exposure time and developing time. The inversely-tapered resist pattern described above is used to perform plating treatment by the method described in the first embodiment so as to form the grid electrode 7. Here, as illustrated in FIG. 31, the first seed surface 6A that extends along the substrate surface of the seed layer 6S forms an acute angle relative to the second seed surface 6B of the side potion of the seed layer 6S. Therefore, after forming a plated electrode, a plated layer pattern has such a cross-sectional shape, in which the second surface 7B that is the outer surface of the plated layer pattern and that is opposed to the second seed surface 6B of the side portion extends at a substantially right angle relative to the first seed surface 6A that extends along the substrate surface.

With this configuration, a right angled triangle shaped pattern in cross section can be obtained, in which the grid electrode 7, configured by a plated layer pattern formed by the first seed surface 6A and the second seed surface 6B, is inclined in a direction opposite to the inclination direction in the first, second, and third embodiments described above. By only changing the resist type, it is possible to obtain the grid electrode 7 with an inversely-tapered shape and a high aspect ratio, while using the same mask design.

Further, by only changing the profile of a resist pattern on the same substrate, it is possible to form an electrode with a different aspect ratio.

### Fifth Embodiment

In a fifth embodiment, a positive resist, by which a forward tapered shape is easily made in principle, is used, and by adjusting the resist exposure time and developing time, it is possible to make a tapered resist pattern. The tapered resist described above is used to perform plating treatment by the method described in the first embodiment. At this time, as illustrated in FIG. 32, the first seed surface 6A that extends along the substrate surface of the seed layer 6S forms an obtuse angle relative to the second seed surface 6B of the side portion of the seed layer 6S. Therefore, after forming a plated electrode, a plated layer pattern has such a cross-sectional shape; in which the first surface 7A that is a side surface of the plated layer pattern and that comes into contact with the second seed surface 6B of the side portion, and an outer surface 7B of the plated layer pattern which is opposed to the first surface 7A, both extend at a substantially obtuse angle relative to the first seed surface 6A that extends along the substrate surface.

With this configuration, a triangular pattern in cross section can be obtained, in which the grid electrode 7 configured by the plated layer pattern is inclined in a direction different from the inclination direction in the first, second, third, and fourth embodiments described above.

### Sixth Embodiment

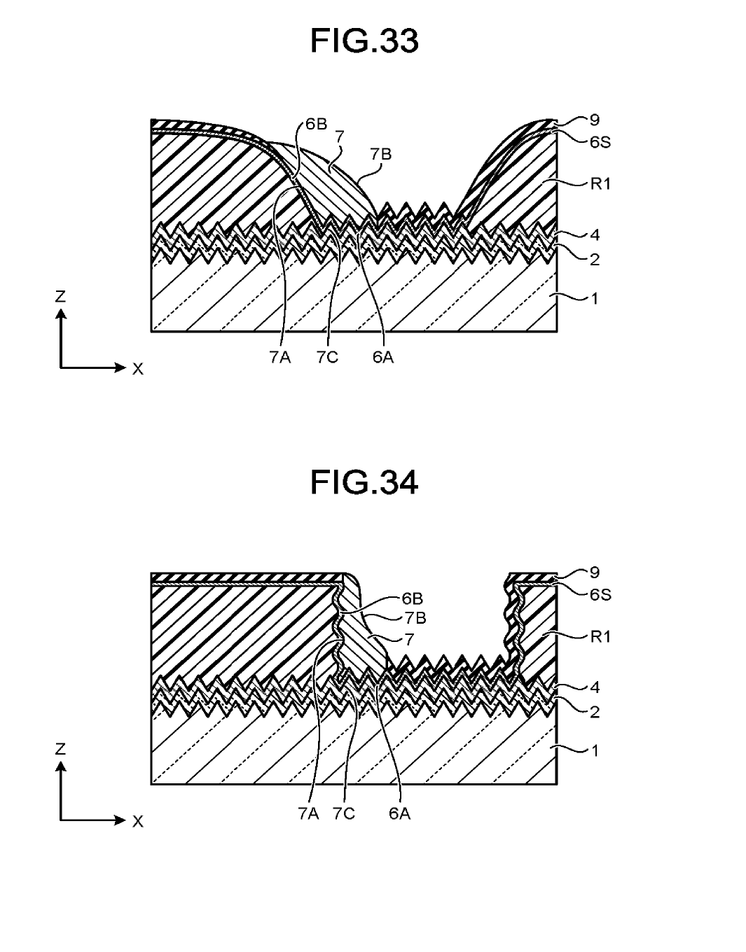

A sixth embodiment describes the grid electrode 7 provided with a rounded plated layer pattern. In the sixth embodiment, a screen printing method, by which the rounded pattern is consequently produced easily, is used to form a resist pattern. Thereafter, plating treatment is performed by the method in the first embodiment. According to this method, the grid electrode 7 is formed with a rounded plated layer pattern in cross section as illustrated in FIG. 33 after forming a plated electrode.

### Seventh Embodiment

Irregularities are formed on a resist wall surface by using an effect of a standing wave during the resist exposure, and thereafter plating treatment is performed by the method in the first embodiment. Here, after a plated electrode is formed, it has a resist pattern shape with irregularities in the cross section as illustrated in FIG. 34. As the surface area of the seed layer 6S is increased, the film-forming speed is increased when a plated layer is formed. Therefore, the plating time needed can be reduced.

As described above, according to the method in a seventh embodiment, the electrode shape can be easily controlled by adjusting the shape of the resist wall surface.

Each shape of the electrodes in the fourth to seventh embodiments described above is advantageous. However, in consideration of the light-shielding area, the solar cell in the fourth to seventh embodiments is sometimes inferior in terms of improvement in output of the solar cell, as compared to the solar cell in which a grid electrode is formed by adapting a nearly-rectangular resist pattern illustrated in the first, second, and third embodiments. However, it is understandable that the solar cell in the fourth to seventh embodiments is also effective as an adjusting method such as forming an electrode structure in order to achieve in-plane uniformity of the output.

### Eighth Embodiment

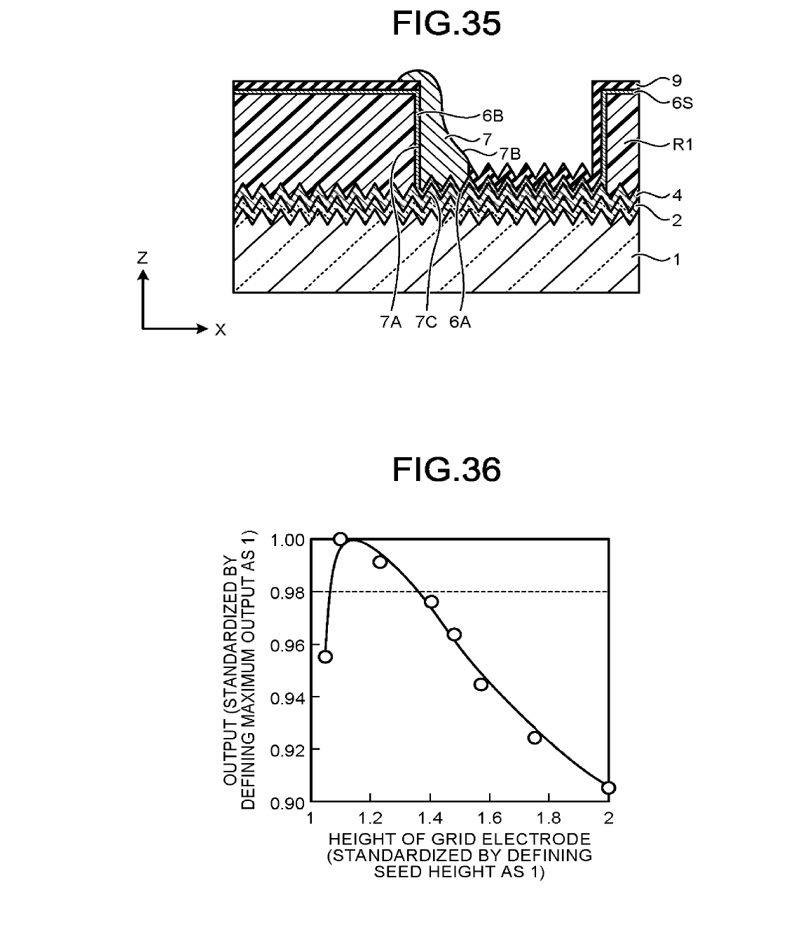

In an eighth embodiment, as illustrated in FIG. 35, by controlling the plating time, it is possible to make a plated electrode that includes the grid electrode 7 constituted of a plated layer pattern with a rounded shape near the peak. In the eighth embodiment, the plating time is long enough so as to form a plated layer that protrudes from the peak of a second seed surface.

According to the eighth embodiment, in the case where the light receiving surface of a solar-battery cell is covered with a translucent surface member and a sealing member, adhesion with the sealing member is improved, and therefore a structure in which cracks are not easily generated can be obtained.

An output of a solar cell is measured, while changing the height of a grid electrode. FIG. 36 illustrates measurement results of a relation between the height of a grid electrode and the output of a solar cell. In this graph, the height of a grid electrode in the Z-axis direction is standardized by defining the height of the second seed surface 6B of the seed layer 6S in the Z-axis direction as 1. The output of the solar cell is standardized by defining the maximum output as 1. Note that the value on the dotted line illustrates an output value of a solar cell when a rectangular plated electrode is produced using a conventional method. With reference to FIG. 36, the maximum output is obtained when the grid height is near 1.1. This is because, although the light-shielding area is increased with an increase in plating time, there is a greater effect in reducing the wire resistance relative to the increase in the light-shielding area. As the plating time is further increased and the height of the grid electrode is further increased, the output of the solar cell is gradually decreased. When the height of the grid electrode exceeds 1.4, there is no advantage over a rectangular electrode. This is because as the plating time is increased, a plated electrode extends in a lateral direction from its bottom and upper portion, which largely increases the light-shielding area. According to the measurement results illustrated in FIG. 36, in order to increase the output of the solar cell, the grid electrode 7 needs to be 1.4 times or less as high in the Z-axis direction as the second seed surface 6B of the seed layer 6S. In other words, it is desirable that the seed layer 6S covers 70% or greater of one side-surface of a plated electrode.

The peak of a plated layer can protrude above the peak of the second seed surface 6B. When the peak height of the second seed surface 6B is equal to or greater than 70% of the peak height of a plated layer that constitutes the grid electrode 7, it is possible to increase the output of the solar cell as described above.

### Ninth Embodiment

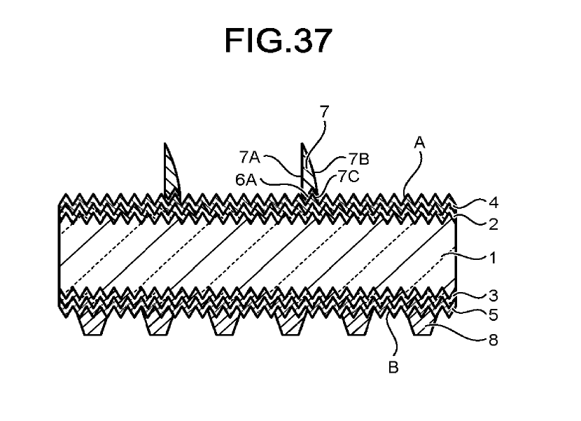

While in the first to eighth embodiments described above, the seed layer 6S is used as a portion of the grid electrode 7; the second seed surface 6B can be etched and removed from the seed layer 6S as illustrated in FIG. 37. Because the other portions are the same as those in the solar cell according to the first embodiment, descriptions thereof are omitted herein.

During manufacturing, in the steps in the first embodiment, after the step of etching the seed layer 6S as illustrated in FIG. 6A, the resist pattern R1 is removed as illustrated in FIG. 6B; and then the step of further etching the seed layer 6S is performed. Therefore, the grid electrode 7 that does not include the second seed surface 6B can be obtained. As another technique, after the grid electrode 7 is formed by a plating method, or after the grid electrode 7 is formed by a plating method illustrated in FIG. 5D, the resist film R1 can be lifted-off to remove the seed layer 6S along with the resist film R1.

With this configuration, the line width of the grid electrode 7 can further be made finer. As a result, it is possible to achieve a further increase in aspect ratio.

According to the present invention, a seed layer that becomes a plated electrode is formed by being deposited not only from the bottom of a resist opening but also from the side surface of the opening. This effectively facilitates formation of a high-aspect-ratio electrode. A plated layer pattern with an inclined surface on one side is formed, which is difficult to be achieved by a general photomechanical technique and plating method. Therefore, light that is incident on the upper portion of the electrode can also contribute to power generation, and accordingly the power generation amount in a solar cell increases.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A solar cell comprising:
a solar-battery cell that has a pn junction;
a light-receiving-surface side electrode
that includes a plurality of grid electrodes that are provided so as to extend in one direction at a given spacing on a light receiving surface of the solar-battery cell, and
that collect a photoelectrically-converted charge; and
a back-surface electrode that is provided on a back surface that opposes to the light receiving surface of the solar-battery cell, wherein
the grid electrode includes
a first seed surface that comes into contact with the light receiving surface of the solar-battery cell,
a second seed surface that is upright to the first seed surface, and is connected to the first seed surface, and
a plated layer that comes into contact with the first seed surface and the second seed surface.

2. The solar cell according to claim 1, wherein
the plated layer is a plated layer that is grown from the first seed surface and the second seed surface, and
the plated layer is oriented with respect to the first seed surface and the second seed surface.

3. The solar cell according to claim 2, wherein
a peak of the plated layer protrudes above a peak of the second seed surface.

4. The solar cell according to claim 3, wherein
a peak height of the second seed surface is equal to or greater than 70% of a peak height of the plated layer.

5. The solar cell according to claim 1, wherein
a surface of the plated layer in contact with the second seed layer is perpendicular to the light receiving surface, and
the plated layer includes an inclined surface on its one side-surface.

6. The solar cell according to claim 1, wherein
the second seed surface is upright in a direction of a normal to the first seed surface, and
the first and second seed surfaces have an L shape in cross section.

7. The solar cell according to claim 2, wherein
the solar-battery cell includes
a first conductivity-type crystal-system silicon substrate, and
a translucent electrode that is formed on a light-receiving-surface side of the crystal-system silicon substrate, and
the first seed surface contacts with the translucent electrode.

8. The solar cell according to claim 2, wherein
the solar-battery cell includes
a first conductivity-type crystal-system silicon substrate,
a second conductivity-type impurity diffusion layer that is formed on a light-receiving-surface side of the crystal-system silicon substrate, and
an anti-reflective film that is formed on a light-receiving-surface side of the impurity diffusion layer, and
the first seed surface contacts with the impurity diffusion layer via a barrier layer and a silicide layer that are formed at an opening of the anti-reflective film.

9. The solar cell according to claim 7, wherein
the first seed surface and the second seed surface are silver layers or copper layers, and
the plated layer is a copper plated layer.

10. The solar cell according to claim 8, wherein
the first seed surface and the second seed surface are silver layers or copper layers, and
the plated layer is a copper plated layer.

11. The solar cell according to claim 8, wherein
the first seed surface and the second seed surface include a barrier layer
that comes into contact with a light receiving surface of the solar-battery cell, and
that is upright in a direction of a normal to the light receiving surface.

12. A manufacturing method for a solar cell, the method comprising:
forming a solar-battery cell that has a pn junction;
forming a light-receiving-surface side electrode that includes a plurality of grid electrodes on a light receiving surface of the solar-battery cell so as to extend in one direction at a given spacing; and
forming a back-surface electrode on a back surface that opposes to the light receiving surface of the solar-battery cell, wherein
the forming a grid electrode includes
forming a resist pattern that includes an opening in a region, where a grid electrode is to be formed, on a light receiving surface of the solar-battery cell,
forming a seed layer in the resist pattern so as to at least include a side surface and a bottom surface facing the opening of the resist pattern,
plating that includes selectively plating the seed layer to form a plated layer, and
detaching the resist pattern.

13. The manufacturing method for a solar cell according to claim 12, wherein
the forming a seed layer
is a step of forming a seed layer entirely over the light receiving surface on which the resist pattern is formed, and
includes a step of forming an insulating film on the seed layer by oblique sputtering prior to the plating step, and
the plating
is a plating step of selectively plating the seed layer that is exposed from the insulating film so as to form a plated layer, and
includes a removing step of removing the insulating film and the seed layer that are exposed out of the plated layer after the plating step.

14. The manufacturing method for a solar cell according to claim 13, wherein
the step of forming an insulating film is a step of forming an insulating film so as to expose
a first seed surface that comes into contact with the light receiving surface, and
a second seed surface that is upright in a direction of a normal to a substrate and is electrically connected to the first seed surface, and
the plating is a selectively plating step of growing a plated layer from the first seed surface and the second seed surface so as to form a plated layer with an inclined surface on at least one side-surface.

15. The manufacturing method for a solar cell according to claim 12, further comprising
forming a barrier layer so as to come into contact with a light receiving surface of the solar-battery cell, and so as to extend along a side wall of the resist prior to the forming a seed layer.

16. The manufacturing method for a solar cell according to claim 13, further comprising
slimming for narrowing the plated layer after the plating step.

17. The manufacturing method for a solar cell according to claim 15, further comprising
slimming for narrowing the plated layer after the plating step.

18. The manufacturing method for a solar cell according to claim 13, wherein
the step of forming an insulating film includes
a step of adjusting a bottom line-width of a grid electrode by adjusting a width of the insulating film, while adjusting an inclination angle at which a substrate is inclined relative to a sputtering direction.

19. The manufacturing method for a solar cell according to claim 15, wherein
the step of forming an insulating film includes
a step of adjusting a bottom line-width of a grid electrode by adjusting a width of the insulating film, while adjusting an inclination angle at which a substrate is inclined relative to a sputtering direction.

20. A solar cell comprising:
a solar-battery cell that has a pn junction;
a light-receiving-surface side electrode that includes a plurality of grid electrodes
that are provided so as to extend in one direction at a given spacing on a light receiving surface of the solar-battery cell, and
that collect a photoelectrically-converted charge; and
a back-surface electrode that is provided on a back surface that opposes to the light receiving surface of the solar-battery cell, wherein
the grid electrode is configured of
a seed surface that comes into contact with the light receiving surface of the solar-battery cell, and
a plated layer that comes into contact with the seed surface, and that includes a side surface that is upright from the seed surface.
